(19) United States
(12) Patent Application Publication
(10) Pub. No.: US 2026/0031828 A1
(43) Pub. Date: Jan. 29, 2026

(54) ADC CALIBRATION DEVICE, DIGITIZER USING ADC CALIBRATION DEVICE, SIGNAL ANALYSIS DEVICE, AND ADC CALIBRATION METHOD

(71) Applicants: Yoshihide GOTO, Atsugi-shi (JP); Jun CHIKAYAMA, Atsugi-shi (JP)

(72) Inventors: Yoshihide GOTO, Atsugi-shi (JP); Jun CHIKAYAMA, Atsugi-shi (JP)

(73) Assignee: ANRITSU CORPORATION, Atsugi-shi (JP)

(21) Appl. No.: 19/266,588

(22) Filed: Jul. 11, 2025

(30) Foreign Application Priority Data
Jul. 29, 2024 (JP) 2024-122267

(51) Int. Cl. H03M 1/10

(52) U.S. Cl. CPC H03M 1/1014

(57) ABSTRACT

In an ADC calibration device, the calibration signal generator generates a frequency modulated wave, as a calibration signal, in which frequency changes in a frequency pattern, which is predetermined, within an applicable frequency range over time. A TI-ADC outputs a sample signal obtained by performing an AD conversion of the calibration signal input. Individual frequency characteristic detection units are provided in parallel corresponding to the plurality of AD converters and individually detect frequency characteristics of the sample signal for each of the plurality of AD converters. In a control unit, a mismatch calculation unit calculates frequency characteristics of mismatch characteristics between the plurality of AD converters from the frequency characteristics of the sample signal for each of the plurality of AD converters, and calculates correction information for correcting a mismatch.

### CROSS-REFERENCE TO RELATED APPLICATIONS

This application claims a priority, under the Paris Convention, to Japanese Patent Application No. 2024-122267 filed on Jul. 29, 2024, the entirety of which is incorporated herein by reference.

### TECHNICAL FIELD

The present disclosure relates to an ADC calibration device that calibrates an AD conversion device that operates multiple AD converters in a time interleaved manner, a digitizer using the ADC calibration device, a signal analysis device, and an ADC calibration method.

### BACKGROUND

Among devices that perform various processing by converting analog signals into digital signal sequence, time-interleaved AD conversion devices (hereinafter also referred to as time-interleaved ADCs or TI-ADCs) are used to perform high-speed signal processing of analog signals. In time-interleaved ADCs, an analog signal to be converted is input to a plurality of AD converters (hereinafter also referred to as ADCs), and a sampling clock of a predetermined period is applied to each of the ADCs in slightly delayed timings, thereby high-speed sampling digital conversion can equivalently be performed.

In time-interleaved ADCs, there is a known technique for correcting mismatches through calibration in order to reduce fluctuations in sample values and generation of spurious signals due to mismatches between individual ADCs (for example, see Patent Literature 1).

Patent Literature 1 discloses a non-conformity correction method of time-interleaved ADCs. In the conventional calibration of the time-interleaved ADCs described in Patent Literature 1 and the like, an unmodulated CW (Continuous Wave) signal (that is a tone signal having a single frequency) is used as a calibration signal. Specifically, by inputting a sine wave signal as an unmodulated CW signal to a time-interleaved ADC and comparing the outputs from each of the ADCs, the degree of mismatch (non-conformity) between the ADCs is measured and the correction of the mismatch is performed. Generally, the mismatch between ADCs has frequency characteristics that the mismatch varies depending on the frequency. Thus, in a measurement of the mismatch, the measurement needs to be performed by changing the frequency of the unmodulated CW signal and the mismatch characteristics through the entire band used should be obtained.

### Patent Literature

Patent Literature 1: Japanese Patent No. 6508665

### SUMMARY

However, in the conventional calibration of the time-interleaved ADCs as described in Patent Literature 1 and the like, it took relatively long time to obtain the mismatched frequency characteristics between the ADCs because a single-tone unmodulated CW signal is used as the calibration signal, and it is necessary to measure each time while varying the frequency within the applicable frequency range. In particular, when the of frequency resolution through a wide band is high, it seriously takes a long time for calibration.

Furthermore, in the calibration of conventional time-interleaved ADCs, the circuit configuration and the control for switching the frequency of the unmodulated CW signal used as the calibration signal, and the cost of the ADC calibration device tends to be increased.

The present disclosure is based on the above-mentioned background, and provides a ADC calibration device, a digitizer using the ADC calibration device, a signal analysis device, and ADC Calibration Method, which can calibrate a time-interleaved ADC at lower cost and in a shorter time even if the time-interleaved ADC has a wide band and high frequency resolution.

In order to resolve the above matter, an ADC calibration device according to claim 1 of the present disclosure is an ADC calibration device (10) that calibrates a TI-ADC (2) that operates a plurality of AD converters (ADCs: 23) in a time interleaved (TI) manner including: a calibration signal generator (1) that generates a frequency modulated wave, as a calibration signal input to the TI-ADC, in which frequency changes in a frequency pattern, which is predetermined, within an applicable frequency range over time; a frequency converter (4) that performs a frequency conversion to extract as an IQ signal from a sample signal obtained in the TI-ADC by performing an AD conversion of the calibration signal at a predetermined sampling frequency by the plurality of AD converters; a serial-parallel conversion unit (5) that outputs the extracted IQ signal to a plurality of signal paths provided in parallel corresponding to the plurality of AD converters; individual frequency characteristic detection units (6a, 6b, 6c) that are provided in each of a plurality of signal paths and individually detect frequency characteristics of the sample signal for each of the plurality of AD converters; a mismatch calculation unit (72) that calculates frequency characteristics of mismatch characteristics between the plurality of AD converters from the frequency characteristics of the sample signal for each of the plurality of AD converters; and a correction information calculation unit (73) that calculates correction information for correcting a mismatch between the plurality of AD converters from the frequency characteristics of the mismatch characteristics, and performs interleave correction for correcting the mismatch based on the correction information.

With this configuration, the ADC calibration device regarding claim 1 of the present disclosure uses the frequency modulated wave having a frequency pattern in which the frequency changes over time within the applicable frequency range as the calibration signal, so there is no need to switch the frequency each time during calibration, the calibration time can be shortened, and the circuit portion that generates the calibration signal and receives the calibration signal to detect the mismatch characteristics between each ADC can be realized with a simple and inexpensive structure. Furthermore, the calibration by selecting a frequency pattern can perform at low cost and in a short time even a time-interleaved ADC with a wide band and high frequency resolution.

Further, the ADC calibration device regarding claim 2 of the present disclosure may be configured such that the calibration signal generator generates the frequency modulated wave having the frequency pattern in which the frequency linearly increases or decreases over time.

With this configuration, the ADC calibration device regarding claim 2 of the present disclosure can easily calculate mismatch characteristics and correction information between ADCs for the applicable frequency range while changing the frequency in a desired frequency pattern that changes linearly by inputting the calibration signal once.

Further, the ADC calibration device regarding claim 3 of the present disclosure may be configured such that the calibration signal generator generates the frequency modulated wave having the frequency pattern in which the frequency increases or decreases stepwise over time.

With this configuration, the ADC calibration device regarding claim 3 of the present disclosure can easily calculate mismatch characteristics and correction information between ADCs for the applicable frequency range while changing the frequency in a desired frequency pattern that changes stepwise by inputting the calibration signal once.

Further, the ADC calibration device regarding claim 4 of the present disclosure, may include a timing detection unit (3) that detects a timing of a start position and an end position of the calibration signal associated with a level on/off pattern which indicates a level-on at a leading position of the calibration signal and the level-off at a trailing position, and may be configured such that the calibration signal generator generates the calibration signal associated with the level on/off pattern, and the frequency converter performs the frequency conversion in an period from the start position to the end position of the calibration signal.

With this configuration, the ADC calibration device regarding claim 4 of the present disclosure can reliably and accurately detect the timing of the start position and the end position of the calibration signal from the level on-off pattern associated with the calibration signal, and can improve the calculation accuracy of the mismatch characteristics between the plurality of AD converters and the correction information for correcting the mismatch between the plurality of AD converters for the applicable frequency range.

Further, the ADC calibration device regarding claim 5 of the present disclosure may include a timing detection unit (3) that detects a timing of a start position of the calibration signal from a trigger signal and estimates a timing of an end position of the calibration signal based on the start position of the calibration signal and the applicable frequency range, in accordance with a process of the AD conversion, and may be configured such that the calibration signal generator generates the trigger signal indicating a timing of a signal-on of the calibration signal in accordance with a generation of the frequency modulated wave, and the frequency converter performs the frequency conversion in a period from the start position to the end position of the calibration signal.

With this configuration, the ADC calibration device regarding claim 5 of the present disclosure can accurately detect the start position of the calibration signal from the signal pattern of the calibration signal, and can also accurately detect the end position of the calibration signal by taking into account the applicable frequency range, and can improve the calculation accuracy of the mismatch characteristics between the plurality of AD converters and the correction information for correcting the mismatch between the plurality of AD converters for the applicable frequency range.

The ADC calibration device regarding claim 6 of the present disclosure may include a applicable frequency range recognition unit (75a) that recognizes the applicable frequency range of the calibration signal; and a sweep speed variable control unit (75) that variably controls a sweep speed by selecting the sweep speed of the calibration signal according to the applicable frequency range recognized.

With this configuration, the ADC calibration device regarding claim 6 of the present disclosure variably controls the sweep speed so that when the applicable frequency range is relatively narrow, the calibration signal is swept at a slower speed, and when the applicable frequency range is relatively wide, it is swept at a faster speed, thereby making it possible to accurately calculate the mismatch characteristics that match the applicable frequency range and correction information.

Further, the ADC calibration device regarding claim 7 of the present disclosure may be configured such that the individual frequency characteristic detection unit individually detects the frequency characteristics regarding amplitude, phase, and DC offset of the sample signal by each of the plurality of AD converters, and the mismatch calculation unit calculates a difference in the frequency characteristics regarding the amplitude, the phase, and the DC offset of the sample signal by each of the plurality of AD converters as the mismatch characteristics between the plurality of AD converters.

With this configuration, the ADC calibration device regarding claim 7 of the present disclosure calculates the mismatch characteristics and correction information between the plurality of AD converters for each item of the amplitude, the phase, and the DC offset, and easily corrects the mismatch related to each item between the plurality of AD converters based on the correction information.

Further, the ADC calibration device regarding claim 8 of the present disclosure may include: a timing interpolation processing unit (72a) that calculates, as interpolated values, values of the amplitude, the phase, and the DC offset of the sample signal at a same frequency at a time for each of the plurality of AD converters by interpolation based on detected values of the amplitude, the phase, and the DC offset of the sample signal by each of the plurality of AD converters, and may be configured such that the mismatch calculation unit calculates the mismatch characteristics between the plurality of AD converters based on the interpolated values of the same frequency at the time calculated by the timing interpolation processing unit.

With this configuration, the ADC calibration device regarding claim 8 of the present disclosure can improve the accuracy of calculating the mismatch characteristics and correction information by calculating the mismatch characteristics between the plurality of AD converters using the values (interpolated values) of the amplitude, the phase, and the DC offset of the sample signal for the same frequency at a time calculated (interpolated) by the timing interpolation processing unit, and can also improve the accuracy of mismatch correction.

The ADC calibration device regarding claim 9 of the present disclosure may include: a temperature sensor (8) that detects a temperature inside a device body; and a calibration timing notification control unit (76) that prompts calibration when the temperature sensor detects either a temperature below or above a temperature range which is preset.

With this configuration, the ADC calibration device regarding claim 9 of the present disclosure is notified that the TI-ADC needs to be calibrated at the timing when the temperature inside the device body falls below or exceeds a preset temperature range, so it is possible to always perform timely calibration, and it is possible to avoid performing an inaccurate AD conversion process without calibration for a long period of time.

Further, the ADC calibration device regarding claim 10 of the present disclosure may include: an interleave correction unit (74) that performs an interleave correction of the TI-ADC to eliminate the mismatch characteristics between the plurality of AD converters based on the correction information calculated by the correction information calculation unit; and a correction information table (74a) storing the correction information corresponding to each temperature within the temperature range, may be configured such that the interleave correction unit performs the interleave correction by obtaining the correction information from the correction information table corresponding to the temperature inside the device body detected by the temperature sensor.

With this configuration, the ADC calibration device regarding claim 10 of the present disclosure has the advantage that, although individual frequency characteristics are often determined depending on temperature, by measuring and storing correction information (correction values) according to temperature in advance as calibration data, the interleave correction can be performed using the calibration data without recalibration.

In order to resolve the above matter, the digitizer regarding claim 11 of the present disclosure may include: a TI-ADC (102) that operates a plurality of AD converters in a time interleaved manner and outputting a sample signal obtained by performing an AD conversion of an input signal (Input) at a predetermined sampling frequency by the plurality of AD converters; and an ADC calibration device (10) that calibrates the TI-ADC, and may be configured such that the ADC calibration device includes: a calibration signal generator (101) that generates a frequency modulated wave, as a calibration signal, in which frequency changes in a frequency pattern, which is predetermined, within an applicable frequency range over time and inputs the calibration signal to the TI-ADC as the input signal; a frequency converter (4) that performs a frequency conversion to extract as an IQ signal from a sample signal obtained in the TI-ADC by performing an AD conversion of the calibration signal at a predetermined sampling frequency by the plurality of AD converters; a serial-parallel conversion unit (5) that outputs the extracted IQ signal to a plurality of signal paths provided in parallel corresponding to the plurality of AD converters; individual frequency characteristic detection units (6a, 6b, 6c) that are provided in each of a plurality of signal paths and individually detect frequency characteristics of the sample signal for each of the plurality of AD converters; a mismatch calculation unit (106) that calculates a frequency characteristic of a mismatch characteristic between the plurality of AD converters from the frequency characteristic of the sample signal for each of the plurality of AD converters; and an interleave correction unit (107) that calculates correction information for correcting a mismatch between the plurality of AD converters from the frequency characteristics of the mismatch characteristics, and performs interleave correction for correcting the mismatch based on the correction information.

With this configuration, the digitizer regarding claim 11 of the present disclosure can improve the calibration accuracy of the TI-ADC by employing an ADC calibration device that can calibrate at lower cost and in a shorter time even a TI-ADC with a wide band and high frequency resolution, and in turn, can improve the basic function of the digitizer that performs the AD conversion of an input signal with the TI-ADC and outputs it.

In order to resolve the above matter, a signal analysis device regarding claim 12 of the present disclosure may include: a frequency converter (151) that converts a analysis target signal into an intermediate frequency and outputs the intermediate frequency; an AD conversion device (156) having a TI-ADC that operates a plurality of AD converters in a time interleaved manner; a signal analysis unit (165) that analyzes the analysis target signal based on a sample signal obtained by performing AD conversions of the analysis target signal, which is the intermediate frequency after frequency conversion, at a predetermined sampling frequency using the plurality of AD converters; and an ADC calibration device (10) that calibrates the TI-ADC, and may be configured such that the ADC calibration device includes: a calibration signal generator (155) that generates a frequency modulated wave, as a calibration signal, in which frequency changes in a frequency pattern, which is predetermined, within an applicable frequency range over time and inputs the calibration signal to the TI-ADC as the input signal; a frequency converter (4) that performs a frequency conversion to extract as an IQ signal from a sample signal obtained in the TI-ADC by performing an AD conversion of the calibration signal at a predetermined sampling frequency by the plurality of AD converters; a serial-parallel conversion unit (5) that outputs the extracted IQ signal to a plurality of signal paths provided in parallel corresponding to the plurality of AD converters; individual frequency characteristic detection units (6a, 6b, 6c) that are provided in each of a plurality of signal paths and individually detect frequency characteristics of the sample signal for each of the plurality of AD converters; a mismatch calculation unit (163) that calculates a frequency characteristic of a mismatch characteristic between the plurality of AD converters from the frequency characteristic of the sample signal for each of the plurality of AD converters; and an interleave correction unit (164) that calculates correction information for correcting a mismatch between the plurality of AD converters from the frequency characteristics of the mismatch characteristics, performs interleave correction for correcting the mismatch based on the correction information, and output a result to the signal analysis unit.

With this configuration, the signal analysis device regarding claim 12 of the present disclosure includes the ADC calibration device that can calibrate the AD conversion device (TI-ADC) with a wide band and high frequency resolution at lower cost and in a shorter time. By adopting a digitizer with improved basic functions for AD converting and outputting signals, it is possible to improve the calibration accuracy of the TI-ADC, and in turn, it is expected to improve the basic functions of a signal analysis device that performs signal analysis by converting the signal to be analyzed using the TI-ADC.

In order to resolve the above matter, an ADC calibration method regarding claim 13 of the present disclosure is an ADC calibration method for calibrating a TI-ADC (2) that operates a plurality of AD converters (ADCs: 23) in a time interleaved manner using a ADC calibration device according to claim 1, including: a calibration signal generation step (S1) that generates a frequency modulated wave, as a calibration signal input to the TI-ADC, in which frequency changes in a frequency pattern, which is predetermined, within an applicable frequency range over time; a frequency conversion step (S4) that performs a frequency conversion to extract as an IQ signal from a sample signal obtained in the TI-ADC by performing an AD conversion of the calibration signal at a predetermined sampling frequency by the plurality of AD converters; a serial-parallel conversion step (S5) that outputs the extracted IQ signal to a plurality of signal paths provided in parallel corresponding to the plurality of AD converters; individual frequency characteristic detection step (S6) that are provided in each of a plurality of signal paths and individually detect frequency characteristics of the sample signal for each of the plurality of AD converters; a mismatch calculation step (S7) that calculates frequency characteristics of mismatch characteristics between the plurality of AD converters from the frequency characteristics of the sample signal for each of the plurality of AD converters; and a correction information calculation step (S8) that calculates correction information for correcting a mismatch between the plurality of AD converters from the frequency characteristics of the mismatch characteristics, and performs interleave correction for correcting the mismatch based on the correction information.

With this configuration, the ADC calibration method regarding claim 13 of the present disclosure uses a frequency modulated wave having a frequency pattern in which the frequency changes over time within the applicable frequency range as the calibration signal, so there is no need to switch the frequency each time during calibration, the calibration time can be shortened, and the circuit portion that generates the calibration signal, receives the calibration signal, and detects the mismatch characteristics between each ADC can be realized with a simple and inexpensive structure. Furthermore, by selecting a frequency pattern, can be calibrated at lower cost and in a shorter time even a time-interleaved ADC with a wide band and high frequency resolution.

Further, the ADC calibration method regarding claim 14 of the present disclosure may be configured such that the calibration signal generation step generates the frequency modulated wave having the frequency pattern in which the frequency linearly increases or decreases over time.

With this configuration, the ADC calibration method regarding claim 14 of the present disclosure can easily calculate mismatch characteristics and correction information between ADCs for the applicable frequency range while changing the frequency in a desired frequency pattern that changes linearly by inputting the calibration signal once.

Further, the ADC calibration method regarding claim 15 of the present disclosure may be configured such that the calibration signal generation step generates the frequency modulated wave having the frequency pattern in which the frequency increases or decreases stepwise over time.

With this configuration, the ADC calibration method regarding claim 15 of the present disclosure can easily calculate mismatch characteristics and correction information between ADCs for the applicable frequency range while changing the frequency in a desired frequency pattern that changes stepwise by inputting the calibration signal once.

Further, the ADC calibration method regarding claim 16 of the present disclosure may be configured such that the calibration signal generation step includes: generating the calibration signal associated with a level on/off pattern which indicates a level-on at a leading position and a level-off at a trailing position of the calibration signal; detecting timings of a start position and an end position of the calibration signal from the level on/off pattern in accordance with a process of the AD conversion; and performing the frequency conversion in an period from the start position to the end position of the calibration signal.

With this configuration, the ADC calibration method regarding claim 16 of the present disclosure can reliably and accurately detect the timing of the start position and the end position of the calibration signal from the level on-off pattern associated with the calibration signal, and can improve the calculation accuracy of the mismatch characteristics between the plurality of AD converters and the correction information for correcting the mismatch between the plurality of AD converters for the applicable frequency range.

Further, the ADC calibration method regarding claim 17 of the present disclosure may be configured such that the calibration signal generation step includes: generating a trigger signal indicating a timing of a signal-on of the calibration signal in accordance with a generation of the frequency modulated wave; detecting a timing of a start position of the calibration signal from the trigger signal and estimating a timing of an end position of the calibration signal based on the start position of the calibration signal and the applicable frequency range, in accordance with a process of the AD conversion; and performing the frequency conversion in a period from the start position to the end position of the calibration signal.

With this configuration, the ADC calibration method regarding claim 17 of the present disclosure can accurately detect the start position of the calibration signal from the signal pattern of the calibration signal, and can also accurately detect the end position of the calibration signal by taking into account the applicable frequency range, and can improve the calculation accuracy of the mismatch characteristics between the plurality of AD converters and the correction information for correcting the mismatch between the plurality of AD converters for the applicable frequency range.

Further, the ADC calibration method regarding claim 18 of the present disclosure may include: recognizing the applicable frequency range of the calibration signal; and controlling a sweep speed variably by selecting the sweep speed of the calibration signal according to the applicable frequency range recognized.

With this configuration, the ADC calibration method regarding claim 18 of the present disclosure variably controls the sweep speed so that when the applicable frequency range is relatively narrow, the calibration signal is swept at a slower speed, and when the applicable frequency range is relatively wide, it is swept at a faster speed, thereby making it possible to accurately calculate the mismatch characteristics that match the applicable frequency range and correction information.

Further, the ADC calibration method regarding claim 19 of the present disclosure may be configured such that the individual frequency characteristic detection step individually detects the frequency characteristics regarding amplitude, phase, and DC offset of the sample signal by each of the plurality of AD converters, and the mismatch calculation step includes: calculating a difference in the frequency characteristics regarding the amplitude, the phase, and the DC offset of the sample signal by each of the plurality of AD converters as the mismatch characteristics between the plurality of AD converters; calculating, as interpolated values, values of the amplitude, the phase, and the DC offset of the sample signal at a same frequency at a time for each of the plurality of AD converters by interpolation based on detected values of the amplitude, the phase, and the DC offset of the sample signal by each of the plurality of AD converters; and calculating the mismatch characteristics between the plurality of AD converters based on the interpolated values of the same frequency at the time calculated by the timing interpolation processing unit.

With this configuration, the ADC calibration method regarding claim 19 of the present disclosure calculates the mismatch characteristics and correction information between the plurality of AD converters for each item of the amplitude, the phase, and the DC offset, and easily corrects the mismatch related to each item between the plurality of AD converters based on the correction information. Further, the ADC calibration device can improve the accuracy of calculating the mismatch characteristics and correction information by calculating the mismatch characteristics between the plurality of AD converters using the values (interpolated values) of the amplitude, the phase, and the DC offset of the sample signal for the same frequency at a time calculated (interpolated) by the timing interpolation processing unit, and can also improve the accuracy of mismatch correction.

Further, the ADC calibration method regarding claim 20 of the present disclosure may include: prompting calibration when the temperature sensor (8), which detects a temperature inside a device body, detects either a temperature below or above a temperature range which is preset; performing an interleave correction of the TI-ADC to eliminate the mismatch characteristics between the plurality of AD converters based on the correction information calculated at the correction information calculation step; and storing the correction information corresponding to each temperature within the temperature range to a correction information table; performing the interleave correction by obtaining the correction information from the correction information table corresponding to the temperature inside the device body detected by the temperature sensor.

With this configuration, the ADC calibration method regarding claim 20 of the present disclosure is notified that the TI-ADC needs to be calibrated at the timing when the temperature inside the device body falls below or exceeds a preset temperature range, so it is possible to always perform timely calibration, and it is possible to avoid performing an inaccurate AD conversion process without calibration for a long period of time. Further, the ADC calibration device has the advantage that, although individual frequency characteristics are often determined depending on temperature, by measuring and storing correction information (correction values) according to temperature in advance as calibration data, the interleave correction can be performed using the calibration data without recalibration.

### Advantageous Effects

The present disclosure can provide an ADC calibration device, a digitizer using the ADC calibration device, a signal analysis device, and ADC Calibration Method, which can calibrate a time-interleaved ADC at lower cost and in a shorter time even if the time-interleaved ADC has a wide band and high frequency resolution.

### BRIEF DESCRIPTION OF DRAWINGS

FIG. 1 is a block diagram showing a schematic configuration of an ADC calibration device according to an embodiment of the present disclosure.

FIG. 2 is a block diagram showing a functional configuration of a control unit in an ADC calibration device according to an embodiment of the present disclosure.

FIG. 3 is a block diagram showing an embodiment of the basic configuration of a TI-ADC in an ADC calibration device according to an embodiment of the present disclosure.

FIG. 4 is a conceptual diagram showing a connection configuration between Sub-ADCs, which is an embodiment of a combination of ADCs subject to mismatch correction.

FIG. 5A is a conceptual diagram showing another embodiment of combination of ADCs subject to mismatch correction, and showing a connection embodiment that TI-ADC consists of a single ADC core.

FIG. 5B is a conceptual diagram showing another embodiment of combination of ADCs subject to mismatch correction, and showing a connection embodiment that TI-ADC switches and uses multiple ADC cores.

FIG. 6A is a diagram showing characteristics of frequency patterns of frequency modulated waves used as calibration signals in an ADC calibration device according to an embodiment of the present disclosure, and showing a pattern that a frequency increases linearly.

FIG. 6B is a diagram showing characteristics of frequency patterns of frequency modulated waves used as calibration signals in an ADC calibration device according to an embodiment of the present disclosure, and showing a pattern that a frequency increases stepwise.

FIG. 7 is a diagram showing an example detecting a residual frequency after frequency conversion of a frequency modulated wave used as a calibration signal in an ADC calibration device according to an embodiment of the present disclosure.

FIG. 8 is a flowchart showing a calibration operation of an ADC calibration device according to an embodiment of the present disclosure.

FIG. 9 is a schematic diagram showing a signal processing system for a calibration signal in an ADC calibration device and showing signal characteristics of a processed signal in the signal processing system according to an embodiment of the present disclosure.

FIG. 10 is a diagram showing a comparison example between the frequency characteristics of the sample signal at Sub-ADC #1 detected by the individual frequency characteristic detection unit 6a and the frequency characteristics of the sample signal at Sub-ADC #2 detected by the individual frequency characteristic detection unit 6b in FIG. 9.

FIG. 11A is a diagram for explaining sampling interpolation in an ADC calibration device according to an embodiment of the present disclosure, showing a characteristic extraction image of sample signals of two ADCs.

FIG. 11B is a diagram for explaining sampling interpolation in an ADC calibration device according to an embodiment of the present disclosure, showing a mismatch characteristic derivation image between ADCs to which the sampling interpolation is applied.

FIG. 12 is a block diagram showing an embodiment of a digitizer according to the present disclosure using an ADC calibration device according to the present disclosure.

FIG. 13 is a block diagram showing an embodiment of a signal analysis device according to the present disclosure that employs a digitizer using an ADC calibration device according to the present disclosure.

### DETAILED DESCRIPTION

Hereinafter, one or more embodiments of an ADC calibration device, a digitizer using the ADC calibration device, a signal analysis device, and an ADC calibration method according to the present disclosure will be described with reference to the drawings.

### ADC Calibration Device

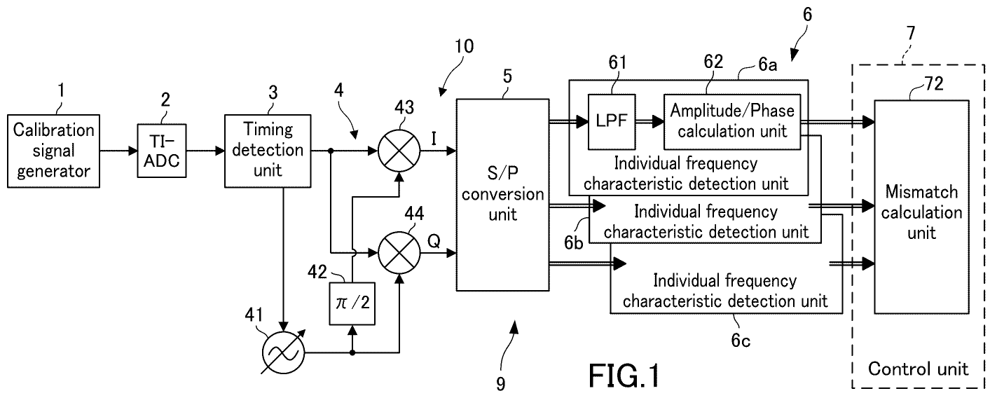

First, the configuration of an ADC calibration device 10 according to an embodiment of the present disclosure will be described. FIG. 1 is a block diagram showing a schematic configuration of an ADC calibration device 10 according to an embodiment of the present disclosure.

As shown in FIG. 1, the ADC calibration device 10 according to the present embodiment is configured to include a calibration signal generator 1, a time-interleaved ADC (hereinafter referred to as TI-ADC) 2, a timing detection unit 3, a frequency converter 4, and a serial parallel conversion unit (hereinafter referred to as an S/P conversion unit) 5, individual frequency characteristic detection units 6a, 6b and 6c (hereinafter sometimes collectively referred to as an individual frequency characteristic detection unit 6), and a control unit 7. The timing detection unit 3, the frequency converter 4, the S/P conversion unit 5, and the individual frequency characteristic detection unit 6 constitute a frequency characteristic monitoring unit 9.

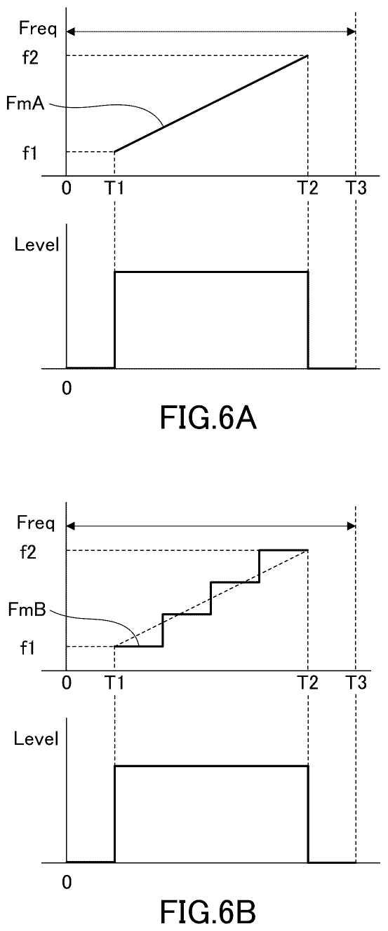

The calibration signal generator 1 generates a calibration signal in a specified frequency range (applicable frequency range). In this embodiment, the calibration signal generator 1 generates a frequency modulated wave (hereinafter referred to as FM modulated wave), as a calibration signal, whose frequency changes over time in predetermined frequency patterns (see FIGS. 6A and 6B) within the applicable frequency range. The calibration signal may further be associated with a signal pattern (see FIGS. 6A and 6B), such as a signal on-off pattern in which the signal is turned on at the leading position of the calibration signal and turned off at the trailing end position.

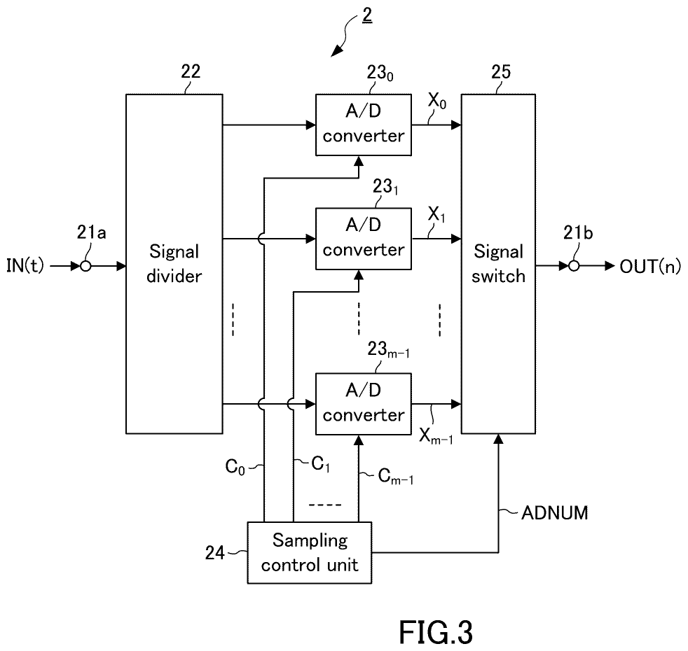

The TI-ADC 2 is composed of multiple ADCs that operate in a time-interleaved manner, and each ADC performs AD conversion on the calibration signal input from the calibration signal generator 1 at a predetermined sampling frequency to generate a sample signal, and sequentially (serially) outputs the sample signal from each ADC. A detailed configuration example of the TI-ADC 2 will be described later with reference to FIG. 3.

The timing detection unit 3 detects the timing of, for example, the start position, the start position and the end position, the end position, etc. of the calibration signal from sample signals of the calibration signals, from a plurality of ADCs sequentially, output by the TI-ADC 2. The timing of the start position and end position of the calibration signal can be detected, for example, based on the above-mentioned signal pattern associated with the calibration signal.

The frequency converter 4 is a functional unit that performs frequency conversion to extract signals as DC signals and as IQ signals from sample signals that are output sequentially in accordance with the AD conversion process that sequentially outputs the sample signals obtained by AD converting the above calibration signal at a predetermined sampling frequency with a plurality of ADCs in the TI-ADC 2.

Specifically, the frequency converter 4 includes a local oscillator 41 that generates a local signal at the timing when the start position etc. of the calibration signal is detected by the timing detection unit 3, a π/2 phase shifter 42 that shifts the phase of the local signal by 90 degrees, a mixer 43 that mixes the sample signal input from the timing detection unit 3 and the local signal from the π/2 phase shifter 42, and a mixer 44 that mixes the sample signal that is input and the local signal from the local oscillator 41. With this configuration, the frequency converter 4 generates a beat signal, as a local signal at the timing when the start position etc. of the calibration signal is detected, equivalent to the sampling signal that is input, and the frequency converter 4 can extract a 0 (zero) frequency signal (baseband signal) by multiplying this beat signal with the sample signal input from the TI-ADC 2. In addition, the frequency converter 4 is configured to orthogonally demodulate the sample signal input from the TI-ADC 2 into an I-phase component and a Q-phase component.

The S/P conversion unit 5 is a functional unit that sequentially (serially) inputs the baseband signal (digital orthogonal demodulated signal of I-phase component and Q-phase component) output from the frequency converter 4, and performs serial/parallel conversion processing to output the input signal to a plurality of signal paths provided in parallel corresponding to each ADC constituting the TI-ADC 2.

The individual frequency characteristic detection unit 6 is a processing circuit that is provided for each signal path corresponding to each of the plurality of ADCs that constitute the TI-ADC 2, and individually detects the frequency characteristics of the sample signals (I-phase component and Q-phase component signals (digital orthogonal demodulated signal)) of each ADC input from the S/P conversion unit 5. This embodiment (see FIG. 1) exemplifies a configuration in which the TI-ADC 2 has three ADCs, and individual frequency characteristic detection units 6a, 6b, and 6c are provided for each of the three signal paths corresponding to each ADC. In the present disclosure, the number of individual frequency characteristic detection units 6 is not limited to three, and it is necessary to provide them corresponding to each ADC constituting the TI-ADC 2. As shown in FIG. 1, each individual frequency characteristic detection unit 6 (6a, 6b, 6c) includes a low-pass filter (hereinafter referred to as LPF) 61 and an amplitude/phase calculation unit 62 that calculates the amplitude and phase of the calibration signal.

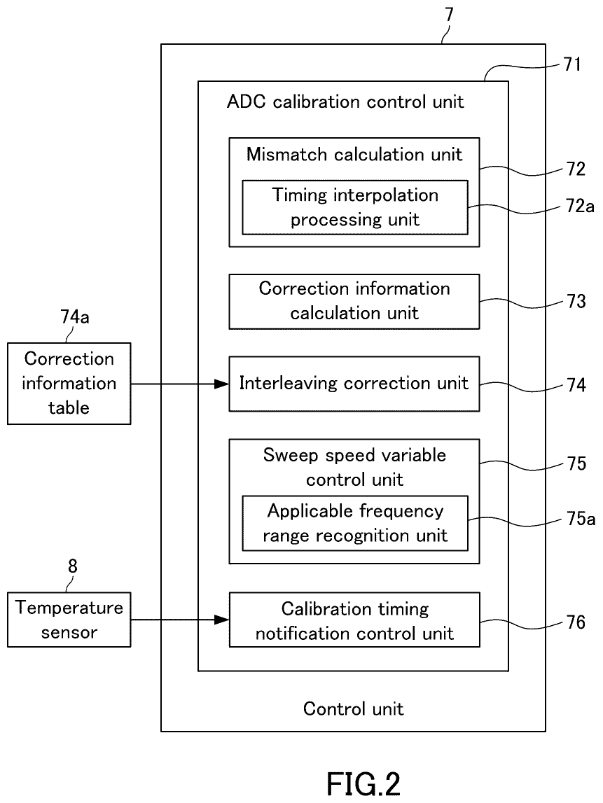

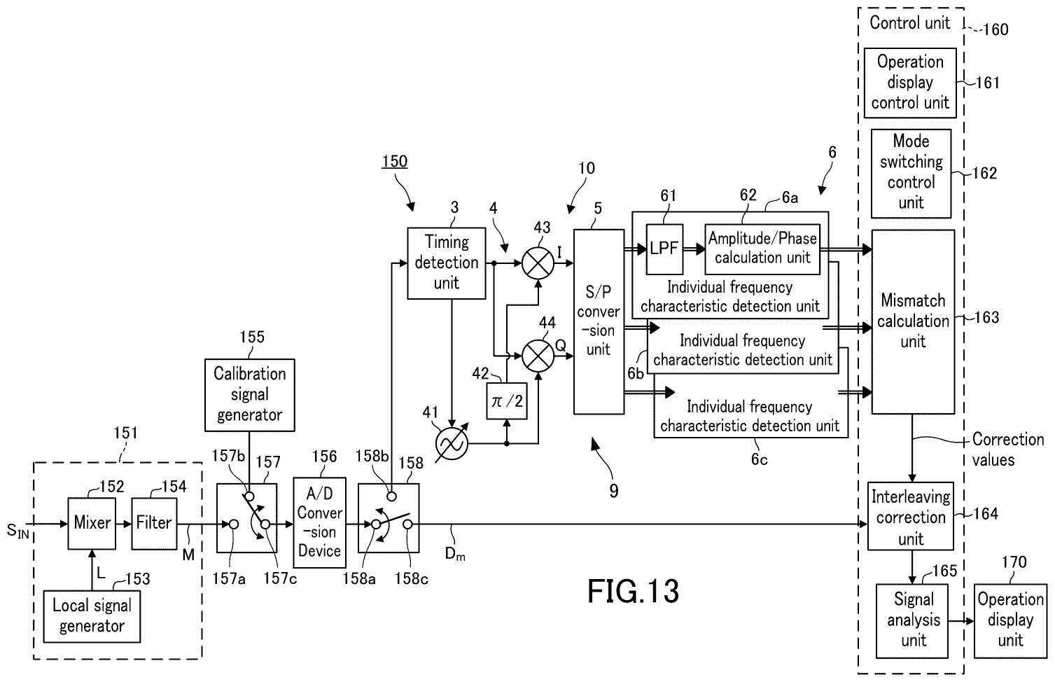

The control unit 7 controls the entire ADC calibration device 10, and as shown in FIG. 2, has an ADC calibration control unit 71 that performs control to calibrate the TI-ADC 2 (calibration control). The ADC calibration control unit 71 includes a mismatch calculation unit 72, a correction information calculation unit 73, an interleave correction unit 74, a sweep speed variable control unit 75, and a calibration timing notification control unit 76 as control function units related to calibration control. Note that in FIG. 1, for convenience, control function units other than the mismatch calculation unit 72 are not shown. Note that the interleave correction unit 74 does not necessarily need to be included in the ADC calibration control unit 71, and may be provided in the control unit (see FIG. 13), for example.

In the configuration of the ADC calibration control unit 71 shown in FIG. 2, the mismatch calculation unit 72 calculates the mismatch characteristics between the ADCs by comparing the frequency characteristics of the sample signals at each ADC detected by the individual frequency characteristic detection units 6a, 6b, and 6c from the sample signals from each ADC, each of three ADCs in this embodiment, constituting the TI-ADC 2. Items of mismatch characteristics to be calculated include relative level (amplitude) ratio and relative timing (phase) difference between sample signals of each ADC, as well as DC offset.

The correction information calculation unit 73 calculates correction information for correcting the mismatch between the three ADCs based on the mismatch characteristics between the ADCs calculated by the mismatch calculation unit 72.

The interleave correction unit 74 is a functional unit that performs control (calibration control) to correct each ADC (interleave correction) so that mismatch characteristics between ADCs are eliminated based on the correction information calculated by the correction information calculation unit 73.

The embodiment of the interleave correction in the interleave correction unit 74 is not limited to using the correction information calculated by the correction information calculation unit 73, but also includes a method of using preset correction information. As an example, FIG. 2 illustrates a configuration in which a correction information table 74a storing correction information corresponding to the temperature (air temperature) inside the device main body of the ADC calibration device 10 is provided, and the interleave correction unit 74 acquires the correction information corresponding to the temperature (air temperature) inside the device main body from the correction information table 74a to perform interleave correction. Here, the interleave correction unit 74 reads the temperature inside the device main body detected by a temperature sensor 8, which will be described later, and obtains correction information corresponding to the temperature from the correction information table 74a. With this configuration, by measuring and storing correction information (correction values) in advance, interleave correction can be performed using the calibration data without recalibrating.

The sweep speed variable control unit 75 is a control function unit that variably controls the sweep speed of the calibration signal, that is, the sweep width per unit time of the calibration signal according to the specified applicable frequency range. Specifically, the sweep speed variable control unit 75 has an applicable frequency range recognition unit 75a that detects (recognizes) an applicable target frequency range prior to calibration, and when the applicable frequency range is recognized as a relatively narrow frequency band, the sweep speed variable control unit 75 decreases the sweep speed of the calibration signal (changes it at a slower speed). On the other hand, when the applicable frequency range is recognized as a relatively wide frequency band, the sweep speed variable control unit 75 increases the sweep speed of the calibration signal (changes it at a faster speed) compared to when the applicable frequency range is relatively narrow. The control to increase or decrease the sweep speed of the calibration signal is, for example, not limited to always controlling at a constant speed within the applicable frequency range (one stroke) of frequency f1 and frequency f2 in FIGS. 6A and 6B, but may include a control to increase or decrease the speed within one stroke, or repeat the changes.

An example of an “appropriate sweep speed” is shown below, which is the case that the appropriate sweep speed is ensured by selecting a sweep speed such that the sweep speed might be increased (accelerated) when the applicable frequency range is wide or the sweep speed might be decreased (slowed) when the applicable frequency range is narrow. In an example of an existing spectrum analyzers, it could be said that 10 GHz is wide and 100 MHz is narrow in terms of analysis bandwidth. Regarding the sweep speed, sweeping 10 GHz in 0.1 seconds corresponds to high speed, and sweeping 10 MHz in 1 second corresponds to low speed. The relationship between the applicable frequency range and the sweep speed described here is just an example, and it is desirable to set the relationship between the applicable frequency range and the sweep speed according to the device model and the like.

The calibration timing notification control unit 76 has a control function to notify the timing to perform the calibration operation of the TI-ADC 2. In order to realize this control function, the ADC calibration device 10 is equipped with a temperature sensor 8 that detects, for example, the temperature inside the device main body of the ADC calibration device 10, as shown in FIG. 2. The calibration timing notification control unit 76 takes in a signal indicating the temperature detected by the temperature sensor 8, and executes a control to notify the user that it is the timing to perform the calibration operation when the detected temperature is either below or above a preset temperature range, for example.

In the ADC calibration device 10 according to the present embodiment, the above-mentioned temperature range (effective temperature range) is set, for example, from 20 degrees Celsius to 30 degrees Celsius. The calibration timing notification control unit 76 may be configured to, for example, generate a predetermined alarm sound to notify that it is the timing to perform the calibration operation when the temperature detected by the temperature sensor 8 exceeds 30 degrees Celsius or falls below 20 degrees Celsius (i.e., deviates from the effective temperature range). The method of notifying the time when the calibration operation should be performed is not limited to generating the above-mentioned alarm sound, but various embodiments may be used, such as, for example, displaying a pop-up message such as “It is time to perform the calibration” on the display unit.

### Time Interleaving Type ADC Conversion Device

Next, the TI-ADC 2 will be explained.

FIG. 3 is a block diagram showing an example of the basic configuration of a TI-ADC 2 in a ADC calibration device 10 (see FIG. 1) according to an embodiment of the present disclosure.

As shown in FIG. 3, the TI-ADC 2 branches the analog input signal IN(t) input to the input terminal 21a into a plurality of (for example, m) signal paths by a signal divider 22 such as a power divider, and inputs the signals to m ADCs 23₀ to 23ₘ₋₁ (hereinafter sometimes collectively referred to as ADCs 23).

The sampling control unit 24 generates sampling clocks C₀ to Cₘ₋₁, each having a period T and whose phase is shifted by ΔT(=T/m), and supplies them to each of the ADCs 23₀ to 23ₘ₋₁, and also supplies the signal switch 25 with a designation signal ADNUM that specifies a ADC which performs the sampling among the ADCs 23₀ to 23ₘ₋₁.

Each ADC 23₀ to 23ₘ₋₁ samples the input value IN when receiving the clock C₀ to Cₘ₋₁, converts it into a digital value, and outputs each sample value X₀, X₁, X₂, . . . , Xₘ₋₁ to the signal switch 25, respectively.

The signal switch 25 sequentially selects sample values X₀, X₁, X₂, . . . output from the ADC specified by the designation signal ADNUM among the ADCs 23₀ to 23ₘ₋₁, and outputs a digital signal sequence OUT (n), in which the sample values are arranged in the order of sampling, to the output terminal 21b.

The digital signal sequence OUT(n) obtained in this way is equivalent to that obtained by sampling the input signal IN(t) at a 1/m sampling period ΔT of the clock period T, and high-speed sampling can be performed using a plurality of low-speed ADCs.

However, when the input signal IN(t) is distributed and input to a plurality of ADCs 23₀ to 23ₘ₋₁ as in the TI-ADC 2 described above, accuracy deviations occur in the result of signal processing to the obtained sample values due to differences in the distribution characteristics of the signal divider 22 itself, the frequency characteristics of the distribution paths, and the differences in the frequency characteristics of each ADC 23₀ to 23ₘ₋₁.

In addition, regarding the clock that determines the sampling timing of each ADC 23₀ to 23ₘ₋₁, timing errors occur due to differences in signal path lengths, differences in delay characteristics of each ADC with respect to the sampling clock, etc., which leads to occur errors in the result of the signal processing of the sample values obtained.

In order to reduce such errors, it is necessary to reduce the influence of non-uniformity (mismatch) in the characteristics from these input terminals to the ADCs. For example, a correction processing unit for correcting mismatch can be provided between each of ADCs 23₀ to 23ₘ₋₁ and the signal switch 25 to improve the accuracy of the TI-ADC 2.

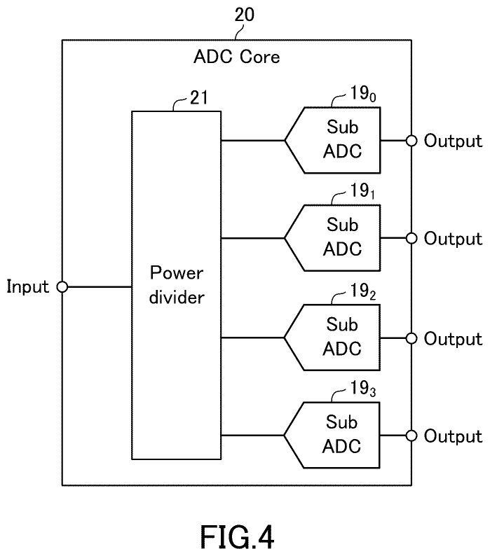

(Combination of ADCs subject to mismatch correction) In the ADC calibration device 10 according to the present embodiment, examples of combinations of ADCs subjected to mismatch correction include, for example, as shown in FIG. 4, a subject configuration such that the ADC core 20 includes sub-ADCs 19₀ to 19₃ which input signals switched by a power divider 21. There is a method of correction of the mismatch between these sub-ADCs 19₀ to 19₃.

The TI-ADC 2 shown in FIG. 3 can be viewed as having a configuration in which the entire TI-ADC 2 forms one ADC core, and each of the ADCs 23₀ to 23ₘ₋₁ is provided as a sub-ADC within the ADC core. That is, the TI-ADC 2 can be one of embodiments of application of mismatch correction between the plurality of sub-ADCs 23₀ to 23₃ within one ADC core 20, as shown in FIG. 4.

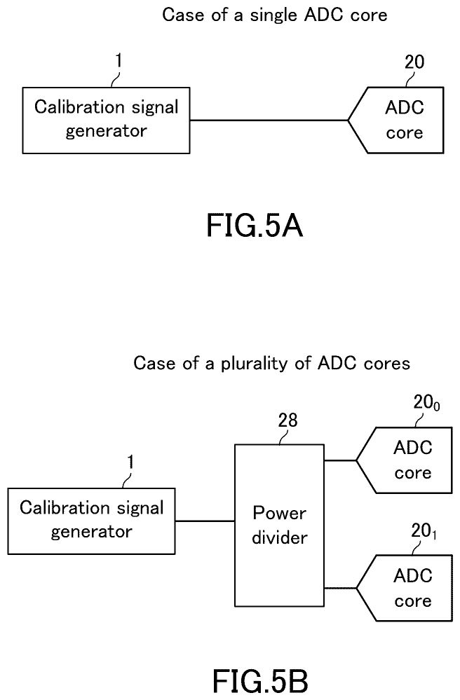

Further, as another example of the combination of ADCs subject to mismatch correction in the ADC calibration device 10 according to the present embodiment, there may be a case in which the subject configuration shown in FIGS. 5A and 5B for example. FIG. 5A shows a configuration example in which the TI-ADC 2 consists of a single ADC core, and FIG. 5B shows a configuration example in which the TI-ADC 2 uses a plurality of ADC cores 20₀ and 20₁ by switching them using the power divider 28. As described above, the ADC calibration device 10 according to the present embodiment is expected to be applied to acquire and correct mismatch characteristics using various combinations between sub-ADCs and between ADC cores as shown in FIGS. 4, 5A and 5B.

The ADC calibration device 10 according to the present embodiment is that an FM modulated wave such as a chirp signal is used as a calibration reference signal in order to easily obtain mismatch characteristics between sub-ADCs and/or between ADC cores. The above-described calibration signal generator 1 is configured to generate, as a calibration signal, an FM modulated wave as shown in FIGS. 6A and 6B which indicates the changes in a predetermined frequency pattern (frequency change pattern) over time within a frequency range (applicable frequency range) subjected to correction (calibration).

By repeatedly inputting an FM modulated wave that covers the applicable frequency range specified in advance as a calibration signal to the TI-ADC 2 and continuing sampling, mismatch characteristics can be detected for frequencies that change in the above-mentioned frequency pattern within the applicable frequency range. In short, in the ADC calibration device 10 according to the present embodiment, the frequency of the calibration signal changes over time within the applicable frequency range each time of input, so unlike conventional devices that use unmodulated CW signals as calibration signals, there is no need to switch the frequency to another frequency within the frequency range applicable to the correction many times, and mismatch characteristics, which covers frequencies within the frequency range applicable to the correction, can be detected by simply repeating the procedure of inputting the FM modulated wave.

FIGS. 6A and 6B are diagrams showing frequency change characteristics (frequency patterns) with respect to time about a calibration signal generated by the calibration signal generator 1 of the ADC calibration device 10 according to an embodiment of the present disclosure. FIG. 6A shows an example of a frequency pattern in which the frequency increases linearly, and FIG. 6B shows an example of a frequency pattern in which the frequency increases stepwise.

First, the FM modulated wave FmA having a frequency pattern shown in FIG. 6A will be explained. As shown in the upper unit of FIG. 6A, the FM modulated wave FmA has a frequency pattern in which the frequency increases at a uniform rate of change (slope) from frequency f1 to frequency f2 during the period from time T1 to T2. The FM modulated wave FmA is not limited to having a uniform rate of change from the frequency f1 to the frequency f2, and may increase (or decrease) while changing in the rate of change in various ways, such as increasing or decreasing.

Furthermore, this FM modulated wave FmA is associated with a signal pattern for identifying the leading position of the calibration signal or the trailing end position of it, or both. The lower unit of FIG. 6A is associated with a level on-off pattern in which the level changes from OFF to ON at time T1 corresponding to the leading position of the calibration signal in response to the frequency change from frequency f1 to frequency f2, and thereafter changes from ON to OFF at time T2 corresponding to the trailing end position of the calibration signal.

Here, in order to associate the level on-off pattern (see the lower unit of FIG. 6A) with the frequency change of the FM modulated wave FmA (see the upper unit of FIG. 6A), the calibration signal generator 1 may be configured to, for example, monitor the frequency of the FM modulated wave FmA, and generate a level on-off pattern in which the level is turned on during the period from when the frequency f1 is detected to when the frequency f2 is detected, in association with the above calibration. On the other hand, a functional unit that generates a level on-off pattern in association with the FM modulated wave (calibration signal) generated by the calibration signal generator 1 may be provided separately from the calibration signal generator 1.

In this case, the above-mentioned timing detection unit 3 (see FIG. 1) can detect the timing of the start position and end position of the calibration signal from the above level on-off pattern in accordance with the AD conversion process in the TI-ADC 2.

Note that the configuration in which the frequency pattern of the FM modulated wave FmA is associated with a signal pattern that makes it possible to identify the leading position and trailing end position of the calibration signal is not limited to the configuration described above. For example, a trigger signal generator may be provided within the calibration signal generator 1 or outside the calibration signal generator 1 to generate a trigger signal indicating the signal-on (head position) timing of the calibration signal in accordance with the generation of the FM modulated wave that is the calibration signal.

In this case, the timing detection unit 3 (see FIG. 1) may be configured to have a function of detecting the timing of the start position of the calibration signal from the above trigger signal in accordance with the AD conversion process in the TI-ADC 2, and estimating the timing of the end position of the calibration signal based on the start position of the calibration signal and the applicable frequency range specified in advance. Here, the trigger signal generator may be configured to generate the trigger signal at both signal-on (head position) and signal-off (trailing end position) timings of the calibration signal. Additionally, the calibration signal generated by the calibration signal generator 1 of the ADC calibration device 10 is not limited to the frequency patterns shown in FIGS. 6A and 6B, but it is also possible to create a chirp signal in any form and use it as a calibration signal.

Next, the FM modulated wave FmB having the signal pattern shown in FIG. 6B will be explained. As shown in the upper unit of FIG. 6B, the FM modulated wave FmB has a frequency pattern in which the frequency increases stepwise (step increase) from frequency f1 to frequency f2 during the period from time T1 to T2. The FM modulated wave FmB is not limited to the example in which the number of steps and change width from frequency f1 to frequency f2 is shown in FIG. 6B, but may increase (or decrease) while changing in various steps and change widths.

The FM modulated wave FmB is also associated with a level on-off pattern in which the level changes from off to on at time T1 corresponding to the start position of the calibration signal, and then from on to off at time T2 corresponding to the rear end position of the calibration signal, as a signal pattern for identifying the start position or the rear end position of the calibration signal, or both.

Here, in order to associate the level on-off pattern (see the lower unit of FIG. 6B) with the frequency change of the FM modulated wave FmB (see the upper unit of FIG. 6B), the calibration signal generator 1 may be configured to, for example, monitor the frequency of the FM modulated wave FmB, and generate a level on-off pattern in which the level is turned on for a period from when the frequency f1 is detected to when the frequency f2 is detected in association with the above calibration. Also, a functional unit that generates a level on-off pattern in association with the FM modulated wave (calibration signal) generated by the calibration signal generator 1 may be provided separately from the calibration signal generator 1.

Even when using the FM modulated wave FmB as the calibration signal, the timing detection unit 3 (see FIG. 1) can detect the timing of the start and end positions of the calibration signal from the above level on-off pattern in accordance with the AD conversion process in TI-ADC 2.

Also, when using the FM modulated wave FmB, as in the case where the FM modulated wave FmA is used, a configuration may be adopted in which a trigger signal generator is installed and the timing of the start position and end position of the calibration signal is detected or estimated based on the trigger signal generated by the trigger signal generator.

Here, the merits of associating signal levels (level on-off patterns, trigger signals, etc.) with the FM modulated waves FmA and FmB will be explained.

### Sampling Timing Detection

The ADC calibration device 10 according to an embodiment of the present disclosure is premised on performing frequency conversion at the same frequency as the calibration signal (see frequency converter 4 in FIG. 1). While the frequency pattern (frequency, time) in the calibration signal is known in advance (see the upper row of FIG. 6A and the upper row of FIG. 6B), the pattern timing is unknown, so it is necessary to understand it from the received signal (the calibration signal input from the calibration signal generator 1). Therefore, when a frequency pattern related to on/off of the signal level (level on-off pattern), for example, shown in the lower unit of FIG. 6A and the lower unit of FIG. 6B is applied to the frequency and the level of the calibration signal, pattern timing detection can be facilitated.

By repeatedly outputting the FM modulated waves FmA and FmB as calibration signals from the calibration signal generator 1 as illustrated in FIGS. 6A and 6B and performing timing detection in detection procedures 1 and 2 shown below, it is possible to detect accurate pattern timing of the received calibration signal.

### Detection Procedure 1

Approximate timing is determined by detecting the rise (or fall) of the signal level of the calibration signal by the timing detection unit 3 (coarse correction).

### Detection Procedure 2

After detecting the approximate timing in detection procedure 1, the frequency converter 4 performs frequency conversion of the calibration signal (process to extract as a DC signal), and detects accurate timing from the frequency difference (precision correction).

By adopting a configuration that detects the timing of the start position and end position (or start position or end position) of the calibration signal using the coarse correction and the precision correction described above, there is no need to use a synchronization circuit or the like between the calibration signal generation circuit and the receiving system, and the cost of the device can also be reduced.

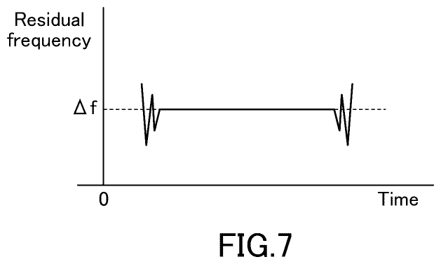

By the way, for example, when the frequency conversion is applied to a calibration signal using a chirp signal as shown in FIG. 6A, the frequency of the baseband signal does not become 0 (zero) in the case of ω(t)≠ω′(t), and appears as a constant frequency difference (Δf) over a certain interval, as shown in FIG. 7 as a detection example of the “residual frequency” after the frequency conversion. The residual frequency indicates a frequency difference (Δf) that appears in the case that the baseband signal frequency does not become 0 (zero) when the frequency conversion is performed to a signal.

This means that a time difference Δt, which can be expressed by the following formula, occurs between the received calibration signal and the frequency conversion pattern.

$$Δ t = \frac{Δ f}{\frac{{f}_{2} - {f}_{1}}{{T}_{2} - {T}_{1}}} \qquad ( Math 1 )$$

By the timing correction at the time of the frequency conversion based on this time difference Δt, the angular frequencies of the received calibration signal and the frequency conversion can be made the same (equivalent to ω(t)=ω′(t−Δt)).

In reality, errors occur due to noise, and frequency characteristics, etc., so accuracy is improved by performing a averaging process within a range that is considered to be a constant interval.

On the other hand, when the frequency varies in steps (see FIG. 6B), the angular frequency of the received calibration signal and the frequency conversion may be made the same in a certain unit only by the timing detection of the coarse correction, and by using only this certain unit to obtain the mismatch characteristics, the precise correction can be omitted. Also, it is expected that the calibration signal generation circuit will be simpler than when only the chirp signal is used.

Although, in FIGS. 6A and 6B, a signal pattern in which the frequency increases linearly or stepwise over time is exemplified as the signal pattern of the FM modulated wave (chirp signal), the signal pattern of the FM modulated wave is not limited to these patterns. A signal pattern in which the frequency decreases linearly or stepwise over time may be applied.

Further, in the ADC calibration device 10 according to the present embodiment, it is possible to improve the analysis accuracy of the calibration signal by applying variable control of the sweep speed, for each of the linearly increasing (or decreasing) frequency pattern and the stepwise increasing (or decreasing) frequency pattern as described above, corresponding to the applicable frequency range of the sweep speed variable control unit 75

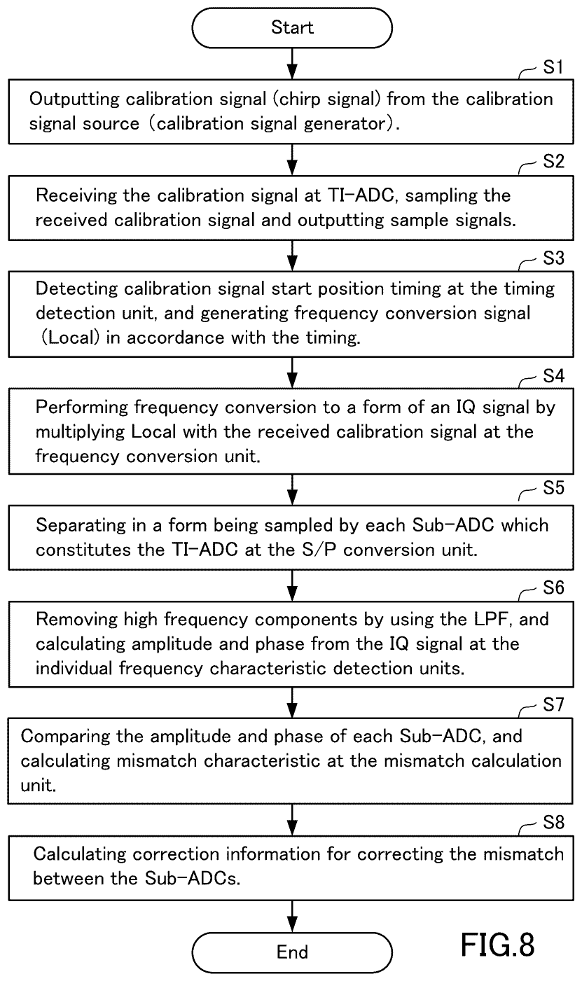

Next, the calibration operation of the ADC calibration device 10 according to the present embodiment will be explained with reference to the flowchart shown in FIG. 8. Here, for convenience, the description will be made on the premise that the TI-ADC 2 of the ADC calibration device 10 is composed of the plurality of Sub-ADCs 23 corresponding to Sub-ADCs 23₀ to 23ₘ₋₁ shown in FIG. 2. and the mismatch correction between these Sub-ADCs 23 (mismatch correction between Sub-ADCs (see FIG. 4)) is performed. This calibration operation can be similarly performed in the case of the mismatch correction between ADC cores (see FIGS. 5A and 5B).

In the ADC calibration device 10 according to the present embodiment, the control unit 7 is configured as a computer device including a CPU (Central Processing Unit), a ROM (Read Only Memory), and a RAM (Random Access Memory) etc.. By executing a predetermined program stored in a ROM or the like, the CPU realizes control functions by each functional block of an ADC calibration control unit 71, a mismatch calculation unit 72, a correction information calculation unit 73, an interleave correction unit 74, a sweep speed variable control unit 75, and a calibration timing notification control unit 76 (sec FIG. 2).

During the calibration control shown in FIG. 8, the ADC calibration control unit 71 collectively controls the calibration signal generator 1, TI-ADC 2, timing detection unit 3, frequency converter 4, S/P conversion unit 5, and individual frequency characteristic detection unit 6 by cooperating with each of the functional blocks described above, and controls the calibration operation to calibrate the TI-ADC 2 according to the following procedure.

To start the calibration operation, first, the ADC calibration control unit 71 performs the drive-control the calibration signal generator 1, which is a calibration signal source, to generates a calibration signal and to output the calibration signal to TI-ADC 2 (step S1). The calibration signal is, for example, an FM modulated wave having a frequency pattern as shown in FIGS. 6A and 6B, and is associated with a signal pattern (timing pattern) such as a level on-off pattern.

On the other hand, the TI-ADC 2 receives the calibration signal output from the calibration signal generator 1 in step S1, performs a process of sampling the received calibration signal (received calibration signal) at a predetermined sampling frequency by each Sub-ADC 23 (see FIG. 3) that constitutes the TI-ADC 2, and sequentially outputs the sample signals obtained by this process to the timing detection unit 3 (step S2).

The timing detection unit 3 inputs the sample signal output by the TI-ADC 2, detects the start position timing of the calibration signal from the timing pattern (for example, the level on-off pattern shown in the lower units of FIGS. 6A and 6B, or the trigger signal described above) associated with the sample signal, and outputs a signal indicating that the detection has been performed to the local oscillator 41 of the frequency converter 4.

As a result, the frequency converter 4 starts the local oscillator 41 at the timing when the above signal is input from the timing detection unit 3, that is, at the start position timing of the calibration signal, and generates a local signal (Local) of the frequency conversion signal in accordance with the start position timing (step S3). Here, the local signal has a negative frequency with respect to the received calibration signal. Thereby, in step S4 described below, by multiplying this local signal with the sample signal from each Sub-ADC 23 of the TI-ADC 2, it becomes possible to extract as an IQ signal having a zero frequency.

As another configuration example for generating the local signal in step S3, the timing detection unit 3 may have a memory to temporarily store the required length of the received calibration signal at the TI-ADC 2, and output it to the next block (frequency converter 4) in synchronization with the output of the local signal.

After generating the local signal in step S3 above, the frequency converter 4 shifts the phase of the local signal with the π/2 phase shifter 42 and inputs it to the mixer 43, and inputs the local signal as it is to the mixer 44, while accepting the sample signal, in each Sub-ADC 23 of the TI-ADC 2 via the timing detection unit 3, to input to the mixers 43 and 44. Thereby, the frequency converter 4 performs the frequency conversion the received calibration signal to the form of an IQ signal by multiplying each local signal with a phase difference of π/2 and the sample signal at each Sub-ADC 23 of the TI-ADC 2 using mixers 43 and 44, respectively (step S4). In this way, the frequency converter 4 performs the frequency conversion process to extract an IQ signal having a zero frequency from the sample signal after AD conversion processing by each Sub-ADC 23 of the TI-ADC 2.

Next, the S/P conversion unit 5 performs serial-parallel conversion processing to output the sample signal (IQ signal) of each Sub-ADC 23, which input as a serial signal from the frequency converter 4 performing the frequency conversion in step S4, to a plurality of signal paths provided in parallel corresponding to each Sub-ADC 23 (step S5). As a result, the IQ signal is separated (distributed) into the signal paths (the signal paths in which the individual frequency characteristic detection units 6a, 6b, and 6c are respectively provided in FIG. 1) corresponding to the Sub-ADC 23 in a form being sampled by each Sub-ADC 23.

Note that FIG. 1 illustrates an S/P conversion process based on a configuration in which the TI-ADC 2 has, for example, three Sub-ADCs 23, and the individual frequency characteristic detection units 6a, 6b, and 6c are provided in three signal paths corresponding to each Sub-ADC 23. The present disclosure is not limited to this, and the S/P conversion process can be performed regardless of the number of Sub-ADCs 23 and the number of the individual frequency characteristic detection units 6 that constitute the TI-ADC 2.

Following the serial-to-parallel conversion process in step S5 above, the individual frequency characteristic detection units 6a, 6b, and 6c corresponding to each Sub-ADC 23 perform processes of detecting the frequency characteristics of the sample signals, corresponding to each Sub-ADC 23, input from the S/P conversion unit 5 respectively. Specifically, the individual frequency characteristic detection units 6a, 6b, and 6c respectively input and filter the sample signal (IQ signal) of the Sub-ADC 23 by using the LPF 61 to remove high frequency components, and the amplitude/phase calculation unit 62 executes a process of calculating the amplitude and phase of the calibration signal from the IQ signal with the high frequency component removed (step S6).

The information on the amplitude and phase of the calibration signal calculated in step S6 above is input to the mismatch calculation unit 72 that constitutes the ADC calibration control unit 71. The mismatch calculation unit 72 compares the amplitude and phase calculated in step S6 for each detection value of the signal path corresponding to each Sub-ADC 23, and calculates the mismatch characteristic between the Sub-ADCs 23 (step S7).

Next, the correction information calculation unit 73 calculates correction information for correcting the mismatch between the Sub-ADCs 23 from the mismatch characteristics between the Sub-ADCs 23 based on the mismatch characteristics between the Sub-ADCs 23 calculated in step S7 (step S8).

Furthermore, the interleave correction unit 74 controls the above-mentioned correction processing unit based on the correction information calculated by the correction information calculation unit 73, and performs the control to correct the mismatch calculated in step S7 between the Sub-ADC 23 subject to the current correction. A well-known technique can be applied to the mismatch correction control performed by the correction processing unit based on the above correction information.

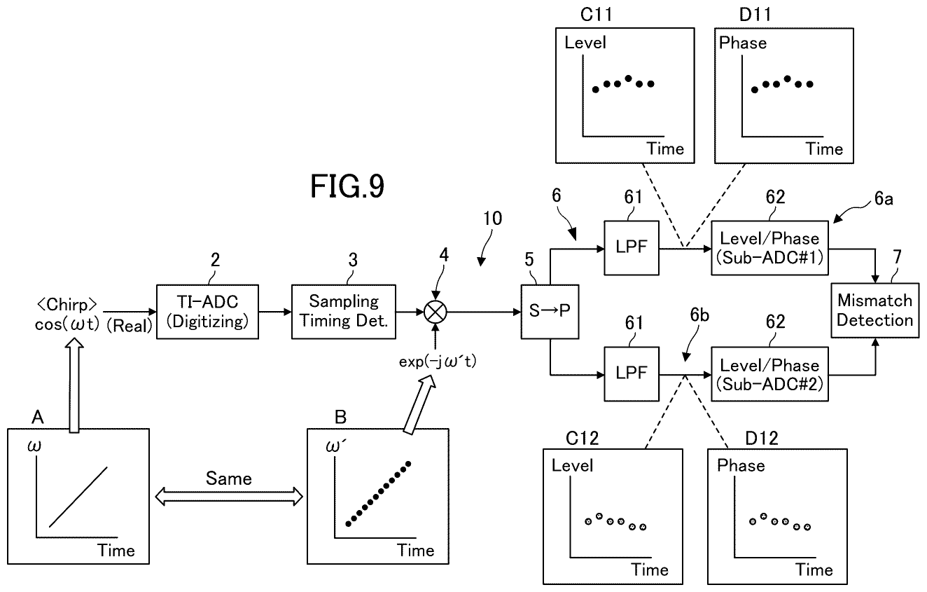

The above series of calibration control operations in the ADC calibration device 10 according to the present embodiment will be described in more detail with reference to FIG. 9.

FIG. 9 is a schematic diagram showing the signal processing system of the calibration signal in the ADC calibration device 10 and the signal characteristics of the processed signal in the signal processing system according to the present embodiment. In FIG. 9, for convenience, a configuration of a signal processing system is illustrated that the TI-ADC 2 includes, for example, two Sub-ADCs 23 (hereinafter referred to as Sub-ADC (#1) and Sub-ADC (#2)) having two individual frequency characteristic detection units 6a and 6b respectively corresponding to Sub-ADC (#1) and Sub-ADC (#2).

In FIG. 9, symbol A indicates the signal characteristic of the calibration signal (FM modulated wave) used in the ADC calibration device 10 according to the present embodiment, and symbol B indicates the signal characteristic of the sample signal after the frequency conversion of the ADC (Sub-ADC (#1)) and ADC (Sub-ADC (#2)) that constitute the TI-ADC 2.

Further, the symbol C11 indicates the frequency characteristic (amplitude characteristic) of a sample signal by the Sub-ADC (#1) flowing through the signal path corresponding to the Sub-ADC (#1), and the symbol C12 indicates the frequency characteristic (amplitude characteristic) of the sample signal by the Sub-ADC (#2) flowing through the signal path corresponding to the Sub-ADC (#2). Furthermore, the symbol D11 indicates the frequency characteristic (phase characteristic) of the sample signal by the Sub-ADC (#1) flowing through the signal path corresponding to the Sub-ADC (#1), and the symbol D12 indicates the frequency characteristic (phase characteristic) of the sample signal by the Sub-ADC (#2) flowing through the signal path corresponding to the Sub-ADC (#2).

As shown in FIG. 9, in the ADC calibration device 10 of this example, the TI-ADC 2 inputs an FM modulated wave having a characteristic (A) that changes linearly over time from the calibration signal generator 1 as a calibration signal.

The TI-ADC 2 inputs and samples the calibration signal by the Sub-ADC (#1) and the Sub-ADC (#2) at respective predetermined sampling frequencies, thereby obtains and outputs the sample signals serially.

The timing detection unit 3 detects the start timing of the calibration signal from the sample signals output from the TI-ADC 2 by the Sub-ADC (#1) and Sub-ADC (#2) based on, for example, a level on-off pattern associated with the calibration signal, and generates a local signal by the local oscillator 41 of the frequency converter 4 at the detected start timing.

Subsequently, the frequency converter 4 inputs the generated local signal and the local signal whose phase has been shifted by π/2, inputs the sample signal by the Sub-ADC (#1) and the sample signal (IQ signal) by the Sub-ADC (#2) of the TI-ADC 2 through the timing detection unit 3, and down-converts the received calibration signal to DC by multiplying them respectively. Here, depending on the frequency of the received calibration signal, up-conversion may be performed.

As shown in characteristic B, the calibration signal after down-conversion takes discrete values with respect to the calibration signal at the time of input (see characteristic (A)). The reason why the calibration signal after down-conversion becomes a discrete value is that the gap time corresponding to the sampling frequency in the AD conversion processing in Sub-ADC (#1) and Sub-ADC (#2) of TI-ADC 2 is reflected.

After that, the S/P conversion unit 5 applies a serial-parallel conversion process to each sample signal, by Sub-ADC (#1) and Sub-ADC (#2), input sequentially from the frequency converter 4 after the down-conversion. The sample signal by the Sub-ADC (#1) is input to the upper signal path in FIG. 9, while the sample signal by the Sub-ADC (#2) is input to the lower signal path in FIG. 9.

After that, in the signal path corresponding to the Sub-ADC (#1), the individual frequency characteristic detection unit 6a filters the sample signal by the Sub-ADC (#1) with the LPF 61, and then the amplitude/phase calculation unit 62 executes a process of detecting the frequency characteristic of the sample signal. Here, the individual frequency characteristic detection unit 62a detects, for example, an amplitude characteristic (Level) illustrated as a characteristic C11 in FIG. 9 and a phase characteristic (Phase) illustrated as a characteristic D11 in the sample signal by the Sub-ADC (#1).

On the other hand, in the signal path corresponding to the Sub-ADC (#2), the individual frequency characteristic detection unit 6b filters the sample signal from the Sub-ADC (#2) with the LPF 61, and then executes a process of detecting the frequency characteristic of the sample signal using the amplitude/phase calculation unit 62. Here, the individual frequency characteristic detection unit 62b detects, for example, an amplitude characteristic (Level) illustrated as a characteristic C12 in FIG. 9 and a phase characteristic (Phase) illustrated as a characteristic D12 in the sample signal by the Sub-ADC (#2).

### Calculation of Mismatch Characteristics

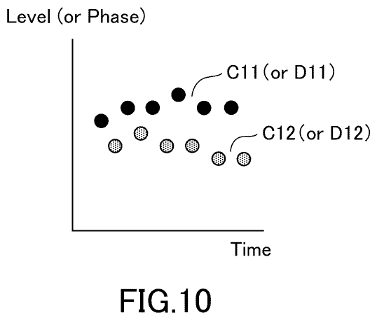

FIG. 10 shows a comparative example of the amplitude characteristic C11 (or phase characteristic D11) of the sample signal by Sub-ADC (#1) detected by the individual frequency characteristic detection unit 6a provided in the signal path in the upper stage of FIG. 9 and the amplitude characteristic C12 (or phase characteristic D12) of the sample signal in Sub-ADC (#2) detected by the individual frequency characteristic detection unit 6b provided in the signal path shown in the lower unit of FIG. 9. In FIG. 10, the upper unit shows an example of detection of a sample signal by Sub-ADC (#1), and the lower unit shows an example of detection of a sample signal by Sub-ADC (#2).

From the comparative example shown in FIG. 10, the following idea can be made about the relationship between the amplitude characteristic C11 of the sample signal by Sub-ADC (#1) and the amplitude characteristic C12 of the sample signal by Sub-ADC (#2). When the frequencies are the same (ωt=ω′t), it is ideally assumed that the two (amplitude characteristic C11 and amplitude characteristic C12) have the same value. However, in reality, due to frequency characteristics and mismatch between Sub-ADC (#1) and Sub-ADC (#2), they have different values (see FIG. 10). Based on such characteristics, the mismatch calculation unit 72 (see FIGS. 1 and 2) can calculate the mismatch characteristic regarding the amplitude between the two by comparing the amplitude characteristic C11 of the sample signal by the Sub-ADC (#1) shown in the upper unit of FIG. 9 with the amplitude characteristic C12 of the sample signal by the Sub-ADC (#2) shown in the lower unit of FIG. 9.

Similarly, the mismatch calculation unit 72 can calculate the mismatch characteristic regarding the phase between the two by comparing the phase characteristic D11 of the sample signal by the Sub-ADC (#2) shown in the upper unit of FIG. 9 with the phase characteristic D12 of the sample signal by the Sub-ADC (#2) shown in the lower unit of FIG. 9.

### Example of Calculation of Mismatch Characteristics

Calculation of mismatch characteristics in the mismatch calculation unit 72 of the ADC calibration device 10 according to the present embodiment will be described using a specific example.

Now, assume that the calibration signal is

$$A cos \{ ω ( t ) \cdot t + Δ θ \}$$

(A indicates amplitude, t indicates time, ω(t) indicates angular frequency, and Δθ indicates initial phase (undefined value)).

At this time, the measurement frequency f can be expressed as the following formula.

$$f ≡ \frac{ω ( t )}{2 π} \qquad ( Math . 2 )$$

When the frequency conversion (down conversion) is performed to this signal at the angular frequency ω′(t), the complex baseband signal f_{BB}(t) is expressed as:

$${f}_{BB} ( t ) = A cos \{ ω ( t ) \cdot t + Δθ \} \times {e}^{- j ω t} = A \cdot \frac{{ε}^{j [ \{ ω ( t ) - {ω}^{′} ( t ) \} t + Δθ ] +} + {ε}^{j [ \{ - ω ( t ) - {ω}^{′} ( t ) \} t + Δθ ]}}{2} . \qquad ( Math . 3 )$$

At this time, if ω(t)=ω′(t), it becomes:

$${f}_{B B} ( t ) = A \cdot \frac{{ε}^{j Δ θ} + {ε}^{j \{ - 2 ω ( t ) + Δ θ \}}}{2} , \qquad ( Math . 4 )$$

by removing the high frequency components with the LPF 61 (see FIGS. 1 and 8), the form can be expressed only by amplitude and initial phase as:

$${f}_{BB} ( t ) = A \cdot \frac{{ε}^{j Δ θ}}{2} . \qquad ( Math . 5 )$$

In the case of TI-ADC, since the amplitude and phase are independent for each path corresponding to Sub-ADC (or ADD core), the baseband signal for each path is as follows:

$${f}_{BB ( k )} ( t ) = {A}_{k} \cdot \frac{{ε}^{j ( Δ θ + {θ}_{k} )}}{2} . \qquad ( Math . 6 )$$

Here, k is the path number, Aₖ is the amplitude, and θₖ is the phase fluctuation.

For example, if you want to obtain the mismatch characteristic based on the path k=0, the calculation of the following expression:

$$\frac{{f}_{BB ( k )} ( t )}{{f}_{BB ( 0 )} ( t )} = \frac{{A}_{k}}{{A}_{0}} \cdot {ε}^{j ( {θ}_{k} - {θ}_{0} )} \qquad ( Math . 7 )$$

makes it possible to obtain mismatch characteristics for each of the amplitude characteristics (gain) and the phase characteristics (timing) at the angular frequency ω(t), that is, the measurement frequency f corresponding to time.

$$\begin{matrix}{Gain}_{k} ( t ) = \vert \frac{{f}_{BB ( k )} ( t )}{{f}_{BB ( 0 )} ( t )} \vert = \frac{{A}_{k}}{{A}_{0}} \\ {Timing}_{k} ( t ) = - arg ( \frac{{f}_{BB ( k )} ( t )}{{f}_{BB ( 0 )} ( t )} ) / ω ( t ) = - \frac{{θ}_{k} - {θ}_{0}}{ω ( t )}\end{matrix} \qquad ( Math . 8 )$$

### Regarding Sampling Interpolation

Regarding the above-mentioned mismatch characteristics, calculation accuracy as high as possible is required from the viewpoint of obtaining accurate correction information for correcting the mismatch characteristics.

Regarding this point, the actual baseband signal (see characteristic B in FIG. 9) is a discrete value, and especially when using a chirp signal as a calibration signal, the sampling timing differs between the Sub-ADCs (or between the ADC cores), causing a deviation in the measurement frequency, which may degrade the accuracy when acquiring the mismatch characteristic.

As a countermeasure, the ADC calibration device 10 according to the present embodiment performs sampling interpolation to eliminate the difference in sampling timing between Sub-ADC (or between ADC cores), so that mismatch correction can be obtained at the same frequency between Sub-ADC (or between ADC cores).

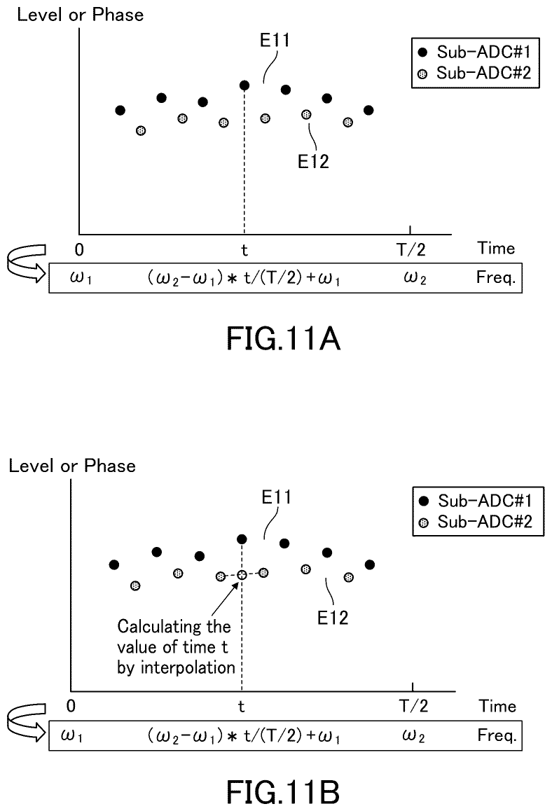

FIGS. 11A and 11B are schematic diagrams for explaining sampling interpolation in the ADC calibration device 10 according to the present embodiment, in which FIG. 11A shows an image of extracting the characteristics of the sample signals of the two Sub-ADCs #1 and #2 that are subject to sampling interpolation, and FIG. 11B shows an image of applying sampling interpolation to the characteristics of the extracted sample signals to derive the mismatch characteristics between Sub-ADCs #1 and #2. Note that in FIGS. 11A and 11B, the horizontal axis is the time axis, the vertical axis is the Level (amplitude) or Phase (phase) axis, and for convenience, the amplitude and phase characteristics are expressed in one graph.

The ADC calibration device 10 according to the present embodiment, during sampling interpolation, for example, as shown in FIG. 11A, converts the sampling timing t to frequency (reading the frequency corresponding to the sampling timing t), and obtain the amplitude and phase characteristics E11 and E12 detected by the individual frequency characteristic detection units 6a and 6b respectively corresponding to Sub-ADC #1 and Sub-ADC #2 for the frequency.

The amplitude and phase characteristics E11 and E12 obtained in this procedure have a frequency deviation due to the difference in sampling timing between Sub-ADC #1 and Sub-ADC #2. Therefore, in the ADC calibration device 10, as the next step, for example, the timing interpolation processing unit 72a (see FIG. 2) provided in the mismatch calculation unit 72 performs interpolation processing to obtain amplitude and phase characteristics for the same frequency. Examples of interpolation include linear interpolation.

Specifically, as shown in FIG. 11B, the timing interpolation processing unit 72a calculates the timing t using, for example, the characteristic E11 of the Sub-ADC #1 as a reference, and obtains the amplitude and phase characteristics E12 for the frequency corresponding to the timing t of the Sub-ADC #2 by linear interpolation or the like. Subsequently, the mismatch calculation unit 72 calculates the mismatch characteristic between the two from the characteristic E11 of Sub-ADC #1 and the characteristic E12 of Sub-ADC #2 for the same frequency obtained.

According to the configuration of the mismatch calculation unit 72 including the timing interpolation processing unit 72a having the sampling interpolation function, the mismatch characteristics can be obtained at the same frequency equivalence for the sample signal by Sub-ADC (#1) and the sample signal by Sub-ADC (#2), and the accuracy of mismatch correction can be improved.

In addition, in FIG. 11B, an example is given in which the timing interpolation processing unit 72a has a sampling interpolation function to obtain characteristics E11 and E12 of the same frequency converted from timing t using the sample signal by Sub-ADC (#1) as a reference.

However, the present disclosure is not limited to this embodiment, and the timing interpolation processing unit 72a may have a function of, for example, using the sample signal from the Sub-ADC (#1) as a reference, and acquiring the characteristics on both sides of the above-mentioned timing t of the sample signal by the Sub-ADC (#1), or the average value of the characteristics on both sides, and using it as a sampling correction value. Even such a sampling interpolation function can sufficiently contribute to improving mismatch correction accuracy depending on the applicable frequency range, frequency pattern, etc. of the calibration signal.

As described above, the ADC calibration device 10 according to the present embodiment is an ADC calibration device 10 that calibrates a TI-ADC 2 that operates a plurality of ADCs 23 in a time interleave (TI) method.

The ADC calibration device 10 according to the present embodiment includes a calibration signal generator 1 that generates a frequency modulated wave whose frequency changes in a predetermined frequency pattern over time within a applicable frequency range as a calibration signal input to the TI-ADC 2, and a calibration signal generator 1 in the TI-ADC 2. A frequency converter 4 performs frequency conversion to extract a sample signal obtained by AD converting a signal at a predetermined sampling frequency by a plurality of ADCs 23 as an IQ signal; a S/P conversion unit 5 that outputs the extracted IQ signal to a plurality of signal paths provided in parallel corresponding to the plurality of ADC 23; individual frequency characteristic detection units 6a, 6b, and 6c that are provided in each of the plurality of signal paths and individually detect the frequency characteristics of the sample signal for each of the plurality of ADCs 23; A mismatch calculation unit 72 that calculates the frequency characteristic of the mismatch characteristic between the plurality of ADCs 23 from the numerical characteristic, and a correction information calculation unit 73 that calculates correction information for correcting the mismatch between the plurality of ADCs 23 from the frequency characteristic of the mismatch characteristic.

With this configuration, the ADC calibration device 10 according to the present embodiment uses a frequency modulated wave having a frequency pattern in which the frequency changes over time within the applicable frequency range as the calibration signal, so there is no need to switch the frequency each time during calibration, the calibration time can be shortened, and the circuit portion that generates the calibration signal and receives the calibration signal and detects the mismatch characteristics between each ADC 23 can be realized with a simple and inexpensive structure. Furthermore, by selecting a frequency pattern, even a time-interleaved ADC with a wide band and high frequency resolution can be calibrated at low cost and in a short time.

Furthermore, the ADC calibration device 10 according to the present embodiment has a configuration in which the calibration signal generator 1 generates a frequency modulated wave having a frequency pattern in which the frequency linearly increases or decreases with time.

With this configuration, the ADC calibration device 10 according to the present embodiment can easily calculate the mismatch characteristics and correction information between the ADCs 23 for the applicable frequency range while changing the frequency in a desired frequency pattern that changes linearly by inputting the calibration signal once.

Further, the ADC calibration device 10 according to the present embodiment has a configuration in which the calibration signal generator 1 generates a frequency modulated wave having a frequency pattern in which the frequency increases or decreases stepwise over time.

With this configuration, the ADC calibration device 10 according to the present embodiment can easily calculate the mismatch characteristics and correction information between the ADCs 23 for the applicable frequency range while changing the frequency in a desired frequency pattern that changes stepwise by inputting the calibration signal once.

In addition, in the ADC calibration device 10 according to the present embodiment, the calibration signal generator 1 generates a calibration signal that is further associated with a level on-off pattern in which the level is turned on at the beginning position of the calibration signal and the level is turned off at the rear end position, and the calibration signal is generated in accordance with the AD conversion process. In addition, it further includes a timing detection unit 3 that detects the timing of the start position and end position of the calibration signal from the level on-off pattern, and a frequency converter 4 that performs the frequency conversion in the unit from the start position to the end position of the calibration signal.

With this configuration, the ADC calibration device 10 according to the present embodiment can reliably and accurately detect the timing of the start position and end position of the calibration signal from the level on-off pattern associated with the calibration signal, and can improve the mismatch characteristics between the plurality of ADCs 23 and the calculation accuracy of correction information for correcting the mismatch between the plurality of ADCs 23 for the applicable frequency range.

Furthermore, in the ADC calibration device 10 according to the present embodiment, the calibration signal generator 1 generates a trigger signal indicating the signal-on timing of the calibration signal in accordance with the generation of the frequency modulated wave, and detects the timing of the start position of the calibration signal from the trigger signal in accordance with the AD conversion process. In addition, it may further include a timing detection unit 3 that estimates the timing of the end position of the calibration signal based on the start position of the calibration signal and the applicable frequency range, and the frequency converter 4 may perform the frequency conversion in the unit from the start position to the end position of the calibration signal.

With this configuration, the ADC calibration device 10 according to the present embodiment can accurately detect the start position of the calibration signal from the signal pattern of the calibration signal, and can also accurately detect the end position of the calibration signal by taking into account the applicable frequency range, and can improve the mismatch characteristics between the plurality of ADCs 23 and the calculation accuracy of correction information for correcting the mismatch between the plurality of ADCs 23 for the applicable frequency range.

The ADC calibration device 10 according to the present embodiment further includes a applicable frequency range recognition unit 75a that recognizes the applicable frequency range of the calibration signal, and a sweep speed variable control unit 75 that variably controls the sweep speed by selecting the sweep speed of the calibration signal according to the recognized applicable frequency range.

With this configuration, the ADC calibration device 10 according to the present embodiment sweeps the calibration signal at a slow speed when the applicable frequency range is relatively narrow, and sweeps the calibration signal at a faster speed when the applicable frequency range is wide. By variably controlling the sweep speed, it is possible to accurately calculate mismatch characteristics that match the applicable frequency range and correction information.

Further, the ADC calibration device 10 according to the present embodiment has a configuration in which the individual frequency characteristic detection units 6a, 6b, and 6c individually detect the frequency characteristics regarding amplitude, phase, and DC offset of the sample signal for each of the multiple ADCs 23, and the mismatch calculation unit 72 calculates the difference in frequency characteristics regarding the amplitude, the phase, and the DC offset of the sample signal for each of the multiple ADCs 23 as the mismatch characteristic between the multiple ADCs 23.

With this configuration, the ADC calibration device 10 according to the present embodiment calculates the mismatch characteristics and correction information between the plurality of ADCs 23 for each item of amplitude, phase, and DC offset, and easily corrects the mismatch related to each item between the plurality of ADCs 23 based on the correction information.

Further, the ADC calibration device 10 according to the present embodiment calculates the values of the amplitude, phase, and DC offset of the sample signal at the same frequency and time for each of the plurality of ADCs 23 by interpolation from the detected values of the amplitude, phase, and DC offset of the sample signal for each of the plurality of ADCs 23. It further includes a timing interpolation processing unit 72a that calculates an interpolation value, and the mismatch calculation unit 72 is configured to calculate the mismatch characteristic between the plurality of ADCs 23 based on the interpolation value at the time of the same frequency calculated by the timing interpolation processing unit 72a.

With this configuration, the ADC calibration device 10 according to the present embodiment can improve the accuracy of calculating the mismatch characteristics and correction information by calculating the mismatch characteristics between the plurality of ADCs 23 using the amplitude, phase, and DC offset values (interpolated values) of the sample signals at the same frequency time calculated (interpolated) by the timing interpolation processing unit 72a, and can also improve the mismatch correction accuracy.

Further, the ADC calibration device 10 according to the present embodiment further includes a temperature sensor 8 that detects the temperature inside the device main body, and a calibration timing notification control unit 76 that prompts the implementation of calibration when the temperature sensor 8 detects either a temperature below or above a preset temperature range.

With this configuration, the ADC calibration device 10 according to the present embodiment is notified that the TI-ADC 2 needs to be calibrated at the timing when the temperature inside the device main body falls below or exceeds a preset temperature range, so it is possible to always carry out timely calibration, and it is possible to avoid inaccurate AD conversion processing being performed without calibration for a long period of time.

The ADC calibration device 10 according to the present embodiment also includes an interleave correction unit 74 that performs interleaving correction of the TI-ADC 2 to eliminate mismatch characteristics between the plurality of ADCs 23 based on the correction information calculated by the correction information calculation unit 73, and a The interleave correction unit 74 further includes a correction information table 74a storing corresponding correction information, and the interleave correction unit 74 has a configuration to obtain correction information corresponding to the temperature inside the device main body detected by the temperature sensor 8 from the correction information table 74a and perform interleave correction.

With this configuration, the ADC calibration device 10 according to the present embodiment has the advantage that, although individual frequency characteristics are often determined depending on temperature, by measuring and storing correction information (correction values) according to temperature in advance as calibration data, interleave correction can be performed using the calibration data without recalibrating.

Further, the ADC calibration method according to the present embodiment is an ADC calibration method that uses the ADC calibration device 10 having the above-described configuration to calibrate a TI-ADC 2 that operates a plurality of ADCs 23 in a time interleaved manner. a calibration signal generation step (S1) that generates a frequency modulated wave that changes in a frequency pattern; a frequency conversion step (S4) that performs frequency conversion to extract the sample signal obtained by AD converting the calibration signal at a predetermined sampling frequency by a plurality of ADCs 23 in the TI-ADC 2 as an IQ signal; A serial-to-parallel conversion step (S5) for outputting the extracted IQ signal to a plurality of signal paths provided in parallel corresponding to the plurality of ADCs 23; an individual frequency characteristic detection step (S6) provided in each of the plurality of signal paths and for individually detecting the frequency characteristics of the sample signal for each of the plurality of ADCs 23; A mismatch calculation step (S7) of calculating a frequency characteristic of a mismatch characteristic between the plurality of ADCs 23 from the frequency characteristic of a sample signal for each C23, and a correction information calculation step (S8) of calculating correction information for correcting the mismatch between the plurality of ADCs 23 from the frequency characteristic of the mismatch characteristic.

According to the ADC calibration method according to the present embodiment, since a frequency modulated wave having a frequency pattern in which the frequency changes over time within the applicable frequency range is used as the calibration signal, there is no need to switch the frequency each time during calibration, the calibration time can be shortened, and the circuit portion that generates the calibration signal, receives the calibration signal, and detects the mismatch characteristics between each ADC 23 can be realized with a simple and inexpensive structure. Furthermore, by selecting a frequency pattern, even a time-interleaved ADC with a wide band and high frequency resolution can be calibrated at low cost and in a short time.

### Digitizer Equipped With ADC Calibration Device

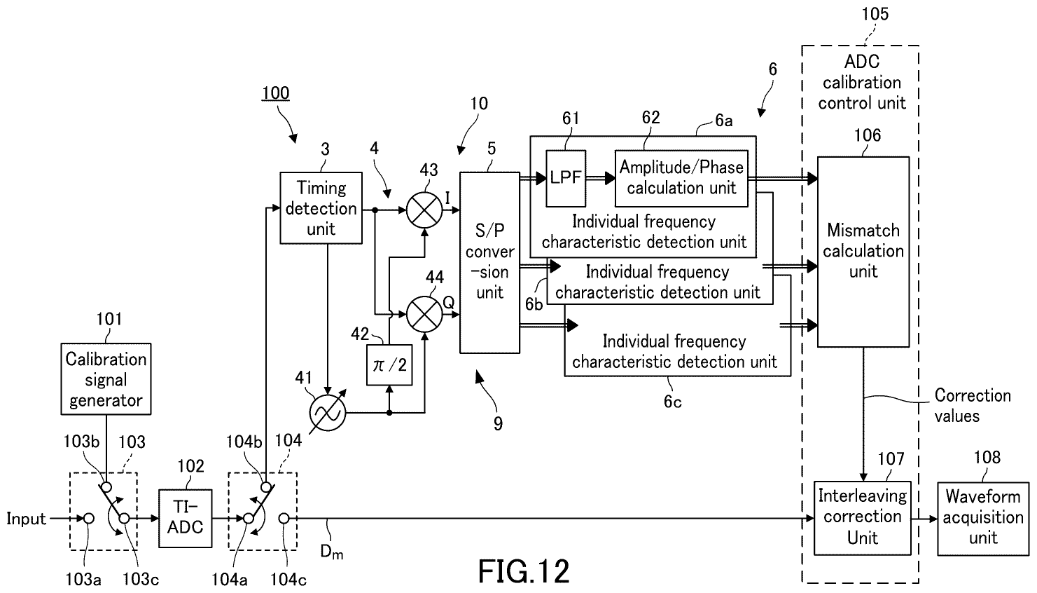

Next, an embodiment of the digitizer according to the present embodiment will be described. FIG. 12 shows a block diagram indicating an embodiment of a digitizer 100 according to the present disclosure using an ADC calibration device according to the present disclosure (see ADC calibration device 10 shown in FIG. 1).

As shown in FIG. 12, the digitizer 100 according to the present embodiment includes a calibration signal generator 101, a TI-ADC 102, path switching units 103 and 104, a frequency characteristic monitoring unit 9, an ADC calibration control unit 105, and a waveform acquisition unit 108.

The path switching unit 103 selectively switches the signal path between either one of the input terminal 103a which inputs the signal to be observed and the input terminal 103b which inputs the calibration signal generated by the calibration signal generator 101, and one output terminal 103c. The path switching unit 103 is not limited to a configuration in which switching is selectively performed, but may be a configuration equivalent to a simple branch (for example, outputting a signal from the input terminal 103a or the input terminal 103b to the output terminal 104c).

The path switching unit 104 selectively switches the signal path between the input terminal 104a which inputs the output signal of the TI-ADC 102, and either one of the output terminal 104b and the output terminal 104c. The path switching unit 104 is not limited to a configuration in which switching is selectively performed, but may be a configuration equivalent to a simple branch (for example, distributing a signal from the input terminal 104a to the output terminal 104b or the output terminal 104c).

In the configuration of the digitizer 100 shown in FIG. 12, the calibration signal generator 101, TI-ADC 102, and frequency characteristic monitoring unit 9 have equivalent configurations as the calibration signal generator 1, TI-ADC 2, and the frequency characteristic monitoring unit 9 (which includes the timing detection unit 3, the frequency converter 4, the S/P conversion unit 5, and the individual frequency characteristic detection unit 6) respectively, which are the components of the above-mentioned ADC calibration device 10 (see FIG. 1).

The ADC calibration control unit 105 is equivalent to the ADC calibration control unit 71 that is a component of the above-described ADC calibration device 10 (see FIG. 1), and includes a mismatch calculation unit 106 and an interleave correction unit 107. Although only the mismatch calculation unit 106 and the interleave correction unit 107 are shown in FIG. 12, it is obvious that the ADC calibration control unit 105 has functional blocks corresponding to the respective functional units in the ADC calibration control unit 71 of the ADC calibration device 10.

As described above, in the digitizer 100 according to the present embodiment, the calibration signal generator 101, the TI-ADC 102, the frequency characteristic monitoring unit 9, and the ADC calibration control unit 105 constitute the ADC calibration device 10 (see FIG. 1) according to the present embodiment. More specifically, the digitizer 100 according to the present embodiment can realize the ADC calibration function equivalent to the ADC calibration device 10 according to the present embodiment by switching the path switching unit 103 so that the input terminal 103b and the output terminal 103c could be connected, and by switching the path switching unit 104 so that the input terminal 104a and the output terminal 104b could be connected. The operating state in which this ADC calibration function can be realized is referred to as, for example, an ADC calibration mode.

On the other hand, the digitizer 100 according to the present embodiment can realize a waveform observation function of a signal (input signal) input from the input terminal 103a by switching the path switching units 103 and 104 to the side opposite to the ADC calibration mode side shown in FIG. 12. An operation mode that can realize this waveform observation function will be referred to as a waveform observation mode, for example.

In the digitizer 100 according to the present embodiment, the ADC calibration mode or the waveform observation mode described above can be set, for example, by manually switching the path switching units 103 and 104. Alternatively, a control unit (not shown) and an operation unit for the entire device including the ADC calibration control unit 105 may be provided, and the control unit may automatically switch between the path switching units 103 and 104 in accordance with the setting operation of the ADC calibration mode or waveform observation mode on the operation unit. The path switching units 103 and 104 may be configured to simply branch signals.

Next, the operation of the digitizer 100 according to this embodiment will be explained. First, the operation in the ADC calibration mode will be explained.

In the ADC calibration mode, in the digitizer 100, a calibration signal, which is an FM modulated wave generated by the calibration signal generator 101, is input to the TI-ADC 102 via the path switching unit 103. The TI-ADC 102 generates sample signals by performing A/D conversion process to the input calibration signals at each ADC, and inputs the sample signals to the frequency characteristic monitoring unit 9 via the path switching unit 104. In the frequency characteristic monitoring unit 9, individual frequency characteristic detection units 6a, 6b, and 6c detect individual frequency characteristics (amplitude, phase) for each sample signal in each ADC constituting the TI-ADC 102 through the above-mentioned signal process by the timing detection unit 3, the frequency converter 4, and the S/P conversion unit 5, and input the detection result to the ADC calibration control unit 105.

In the ADC calibration control unit 105, the mismatch calculation unit 106 obtains frequency characteristics (amplitude, phase) for each sample signal of each ADC from the individual frequency characteristic detection units 6a, 6b, and 6c performing the above described process, compares the frequency characteristics, and calculates the mismatch characteristic regarding the frequency characteristics between each ADC. The interleave correction unit 107 calculates correction information (correction value) that can correct the mismatch characteristic calculated by mismatch calculation unit 106, and controls each ADC constituting TI-ADC 102 to be corrected (interleave correction) using this correction information. This interleave correction is not limited to being performed in the ADC calibration mode, but may be performed during execution of the waveform observation mode.

Next, the operation in waveform observation mode will be explained. In the waveform observation mode, the digitizer 100 outputs an input signal (Input) input from the input terminal 103a of the path switching unit 103 to the output terminal 103c. The input signal may be, for example, an IF signal converted into an intermediate frequency (IF) by a frequency converter (see frequency converter 151 in FIG. 13) of a signal analysis device such as a spectrum analyzer.

The IF signal output to the output terminal 103c of the path switching unit 103 is input to the TI-ADC 102. The TI-ADC 102 generates sample signals by performing a A/D conversion to the input IF signals at each ADC, and outputs the sample signals from the output terminal 104c of the path switching unit 104. The signal (Dm) output from the output terminal 104c of the path switching unit 104 is further input to the waveform acquisition unit 108 via the interleave correction unit 107 in the ADC calibration control unit 105.

Here, the interleave correction unit 107 may perform interleave correction of the ADC by using the correction information already calculated in the ADC calibration mode described above in conjunction with the input of the signal from the TI-ADC 102 via the path switching unit 104.

The waveform acquisition unit 108 performs a process of observing the waveform of the signal input via the interleave correction unit 107. In the waveform observation mode, the waveform of the input signal is acquired through the procedure described above.

According to the configuration of the digitizer 100 according to the present embodiment shown in FIG. 12, in the ADC calibration control function, the calibration of the ADC at an appropriate timing can be performed, and highly accurate waveform observation of the input signal can be performed while reducing mismatch characteristics between the ADCs constituting the TI-ADC 102.

Furthermore, in the configuration shown in FIG. 12, if the ADC calibration control unit 105 has a similar configuration as the ADC calibration control unit 71 (see FIG. 2) of the ADC calibration device 10 (see FIG. 1) described above, each control function of the sweep speed variable control unit 75 and the calibration timing notification control unit 76 can also be used in the digitizer 100 according to the present embodiment.

As a result, the digitizer 100 according to the present embodiment has a sweep speed variable control function of the calibration signal, for example according to the applicable frequency, by the sweep speed variable control unit 75, and also has a control function of notifying the timing to perform the ADC calibration operation by the calibration timing notification control unit 76. Thus, it is also possible to smoothly proceed with calibration control and further enhance convenience when performing the highly accurate waveform observation of the input signal.

In this way, the digitizer 100 according to the present embodiment has a TI-ADC 102 that operates a plurality of ADCs 23 in a time interleaved manner and outputting a sample signal obtained by performing an AD conversion of an input signal (Input) at a predetermined sampling frequency by the plurality of ADCs 23; and an ADC calibration device 10 that calibrates the TI-ADC 102. The ADC calibration device is configured to include: a calibration signal generator 101, which is equivalent to that shown in FIG. 1, that generates a frequency modulated wave, as a calibration signal, whose frequency changes in a predetermined frequency pattern within an applicable frequency range over time and inputs the calibration signal to the TI-ADC 102 as the input signal; a frequency converter 4 that performs a frequency conversion to extract as an IQ signal from a sample signal obtained in the TI-ADC 102 by performing an AD conversion of the calibration signal at a predetermined sampling frequency by the plurality of ADCs 23; a serial-parallel conversion unit 5 that outputs the extracted IQ signal to a plurality of signal paths provided in parallel corresponding to the plurality of ADCs 23; individual frequency characteristic detection units 6a, 6b, 6c that are provided in each of a plurality of signal paths and individually detect frequency characteristics of the sample signal for each of the plurality of ADCs 23; a mismatch calculation unit 106 that calculates a frequency characteristic of a mismatch characteristic between the plurality of ADCs 23 from the frequency characteristic of the sample signal for each of the plurality of ADCs 23; and an interleave correction unit 107 that calculates correction information for correcting a mismatch between the plurality of ADCs 23 from the frequency characteristics of the mismatch characteristics, and performs interleave correction for correcting the mismatch based on the correction information.

With this configuration, since the digitizer 100 according to the present embodiment employs the ADC calibration device 10 that can calibrate at low cost and in a short time, it is possible to improve the calibration accuracy of the TI-ADC 102, and in turn, it is possible to improve the basic function of the digitizer that performs an AD conversion of an input signal by the TI-ADC 102 and outputs it even if TI-ADC 102 has a wide band and high frequency resolution.

### Signal Analysis Device Using the Digitizer Having an ADC Calibration Device

Next, an embodiment of the signal analysis device according to the present disclosure will be described. FIG. 13 is a block diagram illustrating an embodiment of a signal analysis device 150 according to the present disclosure that employs a digitizer according to the present disclosure (see the digitizer 100 shown in FIG. 12).

As shown in FIG. 13, the signal analysis device 150 according to the present embodiment configures to include a frequency converter 151, a calibration signal generator 155, an A/D conversion device 156, path switching units 157 and 158, a frequency characteristic monitoring unit 9, a control unit 160, and an operation display unit 170.

The frequency converter 151 includes a mixer 152, a local oscillator 153, and a filter 154. The frequency converter 151 mixes the input signal SIN and the local signal L generated by the local oscillator 153, and passes the mixed signal through a filter 154 to convert the input signal SIN into an intermediate frequency signal.

A calibration signal generator 155 generates a calibration signal for calibrating a TI-ADC that constitutes an A/D conversion device 156 described later. The calibration signal generator 155 is, for example, equivalent to the calibration signal generator 1 (see FIG. 1), which is a component of the ADC calibration device 10 described above.

The A/D conversion device 156 performs an A/D conversion and outputs the signal (calibration signal, intermediate frequency signal) input via the path switching unit 157, and has a configuration equivalent to, for example, the TI-ADC 2 (see FIGS. 1 and 2) which is a component of the ADC calibration device 10 described above.

The path switching unit 157 selectively switches the signal path between either one of the input terminal 157a which inputs the intermediate frequency signal output by the frequency converter 151 and the input terminal 157b which inputs the calibration signal generated by the calibration signal generator 155, and one output terminal 157c. The path switching unit 157 is not limited to a configuration in which switching is selectively performed, but may be a configuration equivalent to a simple branch (for example, outputting a signal from the input terminal 157a or the input terminal 157b to the output terminal 157c).

The path switching unit 158 selectively switches the signal path between the input terminal 158a which inputs the output signal of the A/D conversion device 156 and either one of the output terminals 158b and 158c to the control unit 160. The path switching unit 158 is not limited to a configuration in which switching is selectively performed, but may be a configuration equivalent to a simple branch (for example, distributing a signal from an input terminal 158a to an output terminal 158b or an output terminal 158c). Here, the output terminal 158b is connected to a mismatch calculation unit 163 in the control unit 160, which will be described later, via the frequency characteristic monitoring unit 9. The output terminal 158c is connected to the signal analysis unit 165 similarly in the control unit 160 via the interleave correction unit 164. The frequency characteristic monitoring unit 9 has an equivalent configuration as the frequency characteristic monitoring unit 9 (which includes a timing detection unit 3, a frequency converter 4, an S/P conversion unit 5, and an individual frequency characteristic detection unit 6) of the ADC calibration device 10 (see FIG. 1) described above.

The control unit 160 includes an operation display control unit 161, a mode switching control unit 162, a mismatch calculation unit 163, an interleave correction unit 164, and a signal analysis unit 165.

The operation display control unit 161 receives operation input from the operation unit of the operation display unit 170, which has the functions of an operation unit and a display unit, and performs a display control for various information to the display unit.

The mode switching control unit 162 is a functional unit that selectively sets an operation mode between the ADC calibration mode and the signal analysis mode of the signal analysis device 150 based on a predetermined mode setting operation input from the operation display unit 170.

When the ADC calibration mode is set, the mismatch calculation unit 163 obtains the frequency characteristics (amplitude, phase) of each sample signal in each ADC constituting the TI-ADC 2 of the A/D conversion device 156, which are calculated by the individual frequency characteristic detection units 6a, 6b, and 6c of the frequency characteristic monitoring unit 9. The mismatch calculation unit 163 calculates the mismatch characteristics regarding the frequency characteristics between each ADC by comparing the frequency characteristics. The interleave correction unit 164 calculates correction information (correction value) that can correct the mismatch characteristic calculated by the mismatch calculation unit 163, and performs interleave correction on each ADC constituting the TI-ADC 2 using this correction information.

The signal analysis unit 165 is a functional unit that performs a analysis process of the signal to be analyzed and to be input to the signal analysis device 150 when the signal analysis mode is set.

The operation display unit 170 includes an operation unit that performs various operations such as setting operations, and a display unit that displays various information such as mismatch characteristics between the ADCs constituting the TI-ADC 2 of the A/D conversion device 156 and signal analysis results. Here, a configuration is illustrated in which the operation display unit 170 has the functions of both the operation unit and the display unit, but the operation display unit 170 may be independently configured as an operation unit and a display unit, respectively.

As described above, in the signal analysis device 150 according to the present embodiment, the calibration signal generator 155, the A/D conversion device (TI-ADC) 156, the frequency characteristic monitoring unit 9, and the mismatch calculation unit 163 in the control unit 160 constitute the above-mentioned ADC calibration device 10 (see FIG. 1). Furthermore, the signal analysis device 150 according to the present embodiment may be configured to include the calibration signal generator 155, the A/D conversion device 156 (TI-ADC), the frequency characteristic monitoring unit 9, and the mismatch calculation unit 163 in the control unit 160. The configuration where the path switching unit 157 for inputting a calibration signal or an intermediate frequency signal to the A/D conversion device 156 is added to this signal analysis device 150 constitutes a digitizer 100 (see FIG. 12) using the above-described ADC calibration device 10 (see FIG. 1).

Next, the operation of the signal analysis device 150 according to this embodiment will be explained. First, the operation in the ADC calibration mode will be explained.

To set the ADC calibration mode, the ADC calibration mode setting operation on the operation display unit 170 is performed. The operation display control unit 161 receives the setting operation, and the mode switching control unit 162 sets the ADC calibration mode based on the setting operation. At this time, the mode switching control unit 162 controls the path switching unit 157 to connect the input terminal 157b and the output terminal 157c, and controls the path switching unit 158 to connect the input terminal 158a and the output terminal 158b.

In the ADC calibration mode, in the signal analysis device 150, a calibration signal, which is an FM modulated wave generated by the calibration signal generator 155, is input to the A/D conversion device 156 via the path switching unit 157. The A/D conversion device 156 has a TI-ADC 2 (see FIGS. 3, 4, and 5), and each ADC performs a A/D conversion process of the input calibration signal to generate a sample signal, and inputs the sample signal to the frequency characteristic monitoring unit 9 via the path switching unit 158. In the frequency characteristic monitoring unit 9, the individual frequency characteristic detection units 6a, 6b, and 6c detect individual frequency characteristics (amplitude, phase) for each sample signal by each ADC constituting the TI-ADC 2 after the above-mentioned signal processes by the timing detection unit 3, the frequency converter 4, and S/P conversion unit 5, and input the detection results to the control unit 160.

In the control unit 160, the mismatch calculation unit 163 obtains the frequency characteristics (amplitude, phase) for each sample signal by each ADC input from the individual frequency characteristic detection units 6a, 6b, and 6c by the above-described process, compares the frequency characteristics, and calculates the mismatch characteristics regarding the frequency characteristics between each ADC. Next, the interleave correction unit 164 calculates correction information (correction value) that can correct the mismatch characteristic calculated by the mismatch calculation unit 163, and uses this correction information to perform the interleave correction on each ADC constituting the TI-ADC 2. After this, for example, in the signal analysis mode, the AD conversion process is performed by the TI-ADC 2 where the interleave correction has been performed.

Next, the operation of the signal analysis mode will be explained. To set the signal analysis mode, a signal analysis mode setting operation on the operation display unit 170 is performed. The operation display control unit 161 receives the setting operation, the mode switching control unit 162 sets the signal analysis mode based on the setting operation, and controls the path switching unit 157 to connect the input terminal 157a and the output terminal 157c, and the path switching unit 158 to connect the input terminal 158a and the output terminal 158c.

In the signal analysis mode, the frequency converter 151 mixes the input signal SIN and the local signal L generated by the local oscillator 153, converts the input signal SIN into signal M as an intermediate frequency by passing it through the filter 154, and outputs the signal M to the path switching unit 157.

The path switching unit 157 outputs the signal M, which is input from the frequency converter 151 to the input terminal 157a after the frequency conversion, to the output terminal 157c. The signal M (IF signal) output to the output terminal 157a of the path switching unit 157 is input to the A/D conversion device 156.

The A/D conversion device 156 has a TI-ADC configuration, performs the A/D conversion process of the input signal M at each ADC, generates a sample signal respectively, and outputs the sample signal from the output terminal 158c of the path switching unit 158.

The signal (Dm) output from the output terminal 158c of the path switching unit 158 is input to the signal analysis unit 165 via the interleave correction unit 164. The signal analysis unit 165 performs a analysis process of the signal to be analyzed after A/D conversion, which is input from the A/D conversion device 156 via the path switching unit 158.

Furthermore, the operation display control unit 161 performs a control to display the analysis result of the signal to be analyzed after the A/D conversion on the display unit of the operation display unit.

According to the configuration of the signal analysis device 150 according to the present embodiment shown in FIG. 13, the ADC calibration mode is set at appropriate timing and the calibration of the TI-ADC of the A/D conversion device 156 is performed, and highly accurate signal analysis of the input signal can be performed while reducing mismatch characteristics between each ADC.

Further, regarding the configuration shown in FIG. 13, the control unit 160 could also be provided with control functions equivalent to the sweep speed variable control unit 75 and the calibration timing notification control unit 76 in the ADC calibration control unit 71 (see FIG. 2) of the ADC calibration device 10 (see FIG. 1) described above.

As a result, the signal analysis device 150 according to the present embodiment has a sweep speed variable control function of the calibration signal corresponding to the applicable frequency, for example, by the sweep speed variable control unit 75, and a control function of notifying the timing to perform the ADC calibration operation by the calibration timing notification control unit 76. It is also possible to proceed with the calibration control smoothly and further improve convenience when performing high-precision signal analysis of the input signal.

In this way, the signal analysis device 150 according to the present embodiment includes a frequency converter 151 that converts a analysis target signal into an intermediate frequency and outputs the intermediate frequency; an A/D conversion device 156 having a TI-ADC that operates a plurality of ADCs 23 in a time interleaved manner; a signal analysis unit 165 that analyzes the analysis target signal based on a sample signal obtained by performing AD conversions of the analysis target signal, which is the intermediate frequency after frequency conversion, at a predetermined sampling frequency using the plurality of ADCs 23; and, an ADC calibration device 10 that calibrates the TI-ADC.

Here, the ADC calibration device 10, which is equivalent to that shown in FIG. 1 (further, by providing a mechanism such as a path switching unit 157 for inputting a calibration signal or an intermediate frequency signal to the A/D conversion device 156, it is equivalent to the digitizer 100 shown in FIG. 12), includes: a calibration signal generator 155 that generates a frequency modulated wave, as a calibration signal, whose frequency changes in a predetermined frequency pattern within an applicable frequency range over time and inputs the calibration signal to the TI-ADC as the input signal; a frequency converter 4 that performs a frequency conversion to extract as an IQ signal from a sample signal obtained in the TI-ADC by performing an AD conversion of the calibration signal at a predetermined sampling frequency by the plurality of ADCs 23; a serial-parallel conversion unit 5 that outputs the extracted IQ signal to a plurality of signal paths provided in parallel corresponding to the plurality of ADCs 23; individual frequency characteristic detection units 6a, 6b, 6c that are provided in each of a plurality of signal paths and individually detect frequency characteristics of the sample signal for each of the plurality of ADCs 23; a mismatch calculation unit 163 that calculates a frequency characteristic of a mismatch characteristic between the plurality of ADCs 23 from the frequency characteristic of the sample signal for each of the plurality of ADCs 23; and an interleave correction unit 164 that calculates correction information for correcting a mismatch between the plurality of ADCs 23 from the frequency characteristics of the mismatch characteristics, performs interleave correction for correcting the mismatch based on the correction information, and output a result to the signal analysis unit 165.

With this configuration, the signal analysis device 150 according to this embodiment could include the ADC calibration device 10 (see FIG. 1) that can calibrate at low cost and in a short time (see FIG. 1), and could employ the digitizer 100 (see FIG. 12) with an improved basic function of performing AD conversion of an input signal and outputting it. Thus, the calibration accuracy of the TI-ADC can be improved, and the basic function of a signal analysis device that performs signal analysis by performing AD conversion of the signal to be analyzed with the TI-ADC can be improved even if TI-ADC 102 has a wide band and high frequency resolution.

### INDUSTRIAL APPLICABILITY

As described above, the present disclosure has the effect that the time interleaved ADC, even which has a wide band and high frequency resolution, can be calibrated at low cost and in a short time. And it is generally useful for ADC calibration devices that includes the above time interleaved ADC and perform calibration, digitizers using the ADC calibration device, signal analysis devices, and ADC calibration methods.

### DESCRIPTION OF REFERENCE NUMERALS AND SIGNS

1 Calibration signal generator
2 Time interleaved ADC (TI-ADC)
3 Timing detection unit
4, 151 Frequency converter
5 Serial-parallel conversion unit (S/P conversion unit)
6, 6a, 6b, 6c Individual frequency characteristic detection unit
7, 160 Control unit
8 Temperature sensor
9 Frequency characteristics monitoring unit
10 ADC calibration device
190, 191, 192, 193 Sub-ADC
20, 200, 201 ADC core
21, 28 Power divider
22 Signal divider
23, 23₀, 23₁, . . . , 23ₘ₋₁ A/D converter (ADC)
24 Sampling control unit
25 Signal switch
61 Low pass filter (LPF)
62 Amplitude/phase calculation unit
71 ADC calibration control unit
72, 163 Mismatch calculation unit
72a Timing interpolation processing unit
73 Correction information calculation unit
74 Interleave correction unit
75 Sweep speed variable control unit
75a Applicable frequency range recognition unit
76 Calibration timing notification control unit
100 Digitizer
101, 155 Calibration signal generator
102 TI-ADC
103 Path switching unit (first path switching unit)
104 Path switching unit (second path switching unit)
105 ADC calibration control unit
106, 163 Mismatch calculation unit
107, 164 Interleave correction unit
108 Waveform acquisition unit
150 Signal analysis device
156 A/D conversion device (TI-ADC)
157 Path switching unit (input path switching unit)
158 Path switching unit (output path switching unit)
160 Control unit
161 Operation display control unit
162 Mode switching control unit
165 Signal Analysis unit
170 Operation display unit

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. An ADC calibration device that calibrates a TI-ADC that operates a plurality of AD converters in a time interleaved manner comprising:
a calibration signal generator that generates a frequency modulated wave, as a calibration signal input to the TI-ADC, in which frequency changes in a frequency pattern, which is predetermined, within an applicable frequency range over time;
a frequency converter that performs a frequency conversion to extract as an IQ signal from a sample signal obtained in the TI-ADC by performing an AD conversion of the calibration signal at a predetermined sampling frequency by the plurality of AD converters;
a serial-parallel conversion unit that outputs the extracted IQ signal to a plurality of signal paths provided in parallel corresponding to the plurality of AD converters;
individual frequency characteristic detection units that are provided in each of a plurality of signal paths and individually detect frequency characteristics of the sample signal for each of the plurality of AD converters;
a mismatch calculation unit that calculates frequency characteristics of mismatch characteristics between the plurality of AD converters from the frequency characteristics of the sample signal for each of the plurality of AD converters; and
a correction information calculation unit that calculates correction information for correcting a mismatch between the plurality of AD converters from the frequency characteristics of the mismatch characteristics, and performs interleave correction for correcting the mismatch based on the correction information.

2. The ADC calibration device according to claim 1, wherein the calibration signal generator generates the frequency modulated wave having the frequency pattern in which the frequency linearly increases or decreases over time.

3. The ADC calibration device according to claim 1, wherein the calibration signal generator generates the frequency modulated wave having the frequency pattern in which the frequency increases or decreases stepwise over time.

4. The ADC calibration device according to claim 1, further comprising
a timing detection unit that detects a timing of a start position and an end position of the calibration signal associated with a level on/off pattern which indicates a level-on at a leading position of the calibration signal and the level-off at a trailing position, wherein:
the calibration signal generator generates the calibration signal associated with the level on/off pattern;
the frequency converter performs the frequency conversion in an period from the start position to the end position of the calibration signal.

5. The ADC calibration device according to claim 1, further comprising
a timing detection unit that detects a timing of a start position of the calibration signal from a trigger signal and estimates a timing of an end position of the calibration signal based on the start position of the calibration signal and the applicable frequency range, in accordance with a process of the AD conversion, wherein
the calibration signal generator generates the trigger signal indicating a timing of a signal-on of the calibration signal in accordance with a generation of the frequency modulated wave, and
the frequency converter performs the frequency conversion in a period from the start position to the end position of the calibration signal.

6. The ADC calibration device according to claim 1, further comprising:
a applicable frequency range recognition unit that recognizes the applicable frequency range of the calibration signal; and
a sweep speed variable control unit that variably controls a sweep speed by selecting the sweep speed of the calibration signal according to the applicable frequency range recognized.

7. The ADC calibration device according to claim 1, wherein
the individual frequency characteristic detection unit individually detects the frequency characteristics regarding amplitude, phase, and DC offset of the sample signal by each of the plurality of AD converters, and
the mismatch calculation unit calculates a difference in the frequency characteristics regarding the amplitude, the phase, and the DC offset of the sample signal by each of the plurality of AD converters as the mismatch characteristics between the plurality of AD converters.

8. The ADC calibration device according to claim 7, further comprising:
a timing interpolation processing unit that calculates, as interpolated values, values of the amplitude, the phase, and the DC offset of the sample signal at a same frequency at a time for each of the plurality of AD converters by interpolation based on detected values of the amplitude, the phase, and the DC offset of the sample signal by each of the plurality of AD converters; wherein
the mismatch calculation unit calculates the mismatch characteristics between the plurality of AD converters based on the interpolated values of the same frequency at the time calculated by the timing interpolation processing unit.

9. The ADC calibration device according to claim 1, further comprising:
a temperature sensor that detects a temperature inside a device body;
a calibration timing notification control unit that prompts calibration when the temperature sensor detects either a temperature below or above a temperature range which is preset.

10. The ADC calibration device according to claim 9, further comprising:
an interleave correction unit that performs an interleave correction of the TI-ADC to eliminate the mismatch characteristics between the plurality of AD converters based on the correction information calculated by the correction information calculation unit; and
a correction information n table storing the correction information corresponding to each temperature within the temperature range, wherein
the interleave correction unit performs the interleave correction by obtaining the correction information from the correction information table corresponding to the temperature inside the device body detected by the temperature sensor.

11. A digitizer comprising:
a TI-ADC that operates a plurality of AD converters in a time interleaved manner and outputting a sample signal obtained by performing an AD conversion of an input signal (Input) at a predetermined sampling frequency by the plurality of AD converters; and
an ADC calibration device that calibrates the TI-ADC, wherein
the ADC calibration device includes:
a calibration signal generator that generates a frequency modulated wave, as a calibration signal, in which frequency changes in a frequency pattern, which is predetermined, within an applicable frequency range over time and inputs the calibration signal to the TI-ADC as the input signal;
a frequency converter that performs a frequency conversion to extract as an IQ signal from a sample signal obtained in the TI-ADC by performing an AD conversion of the calibration signal at a predetermined sampling frequency by the plurality of AD converters;
a serial-parallel conversion unit that outputs the extracted IQ signal to a plurality of signal paths provided in parallel corresponding to the plurality of AD converters;
individual frequency characteristic detection units that are provided in each of a plurality of signal paths and individually detect frequency characteristics of the sample signal for each of the plurality of AD converters;
a mismatch calculation unit that calculates a frequency characteristic of a mismatch characteristic between the plurality of AD converters from the frequency characteristic of the sample signal for each of the plurality of AD converters; and
an interleave correction unit that calculates correction information for correcting a mismatch between the plurality of AD converters from the frequency characteristics of the mismatch characteristics, and performs interleave correction for correcting the mismatch based on the correction information.

12. A signal analysis device comprising:
a frequency converter that converts a analysis target signal into an intermediate frequency and outputs the intermediate frequency;
an AD conversion device having a TI-ADC that operates a plurality of AD converters in a time interleaved manner;
a signal analysis unit that analyzes the analysis target signal based on a sample signal obtained by performing AD conversions of the analysis target signal, which is the intermediate frequency after frequency conversion, at a predetermined sampling frequency using the plurality of AD converters; and,
an ADC calibration device that calibrates the TI-ADC, wherein,
the ADC calibration device includes:
a calibration signal generator that generates a frequency modulated wave, as a calibration signal, in which frequency changes in a frequency pattern, which is predetermined, within an applicable frequency range over time and inputs the calibration signal to the TI-ADC as the input signal;
a frequency converter that performs a frequency conversion to extract as an IQ signal from a sample signal obtained in the TI-ADC by performing an AD conversion of the calibration signal at a predetermined sampling frequency by the plurality of AD converters;
a serial-parallel conversion unit that outputs the extracted IQ signal to a plurality of signal paths provided in parallel corresponding to the plurality of AD converters;
individual frequency characteristic detection units that are provided in each of a plurality of signal paths and individually detect frequency characteristics of the sample signal for each of the plurality of AD converters;
a mismatch calculation unit that calculates a frequency characteristic of a mismatch characteristic between the plurality of AD converters from the frequency characteristic of the sample signal for each of the plurality of AD converters; and
an interleave correction unit that calculates correction information for correcting a mismatch between the plurality of AD converters from the frequency characteristics of the mismatch characteristics, performs interleave correction for correcting the mismatch based on the correction information, and output a result to the signal analysis unit.

13. An ADC calibration method for calibrating a TI-ADC that operates a plurality of AD converters in a time interleaved manner using a ADC calibration device according to claim 1, comprising:
a calibration signal generation step that generates a frequency modulated wave, as a calibration signal input to the TI-ADC, in which frequency changes in a frequency pattern, which is predetermined, within an applicable frequency range over time and inputs the calibration signal to the TI-ADC as the input signal;
a frequency conversion step that performs a frequency conversion to extract as an IQ signal from a sample signal obtained in the TI-ADC by performing an AD conversion of the calibration signal at a predetermined sampling frequency by the plurality of AD converters;
a serial-parallel conversion step that outputs the extracted IQ signal to a plurality of signal paths provided in parallel corresponding to the plurality of AD converters;
individual frequency characteristic detection step that are provided in each of a plurality of signal paths and individually detect frequency characteristics of the sample signal for each of the plurality of AD converters;
a mismatch calculation step that calculates frequency characteristics of mismatch characteristics between the plurality of AD converters from the frequency characteristics of the sample signal for each of the plurality of AD converters; and
a correction information calculation step that calculates correction information for correcting a mismatch between the plurality of AD converters from the frequency characteristics of the mismatch characteristics, and performs interleave correction for correcting the mismatch based on the correction information.

14. The ADC calibration method according to claim 13, wherein the calibration signal generation step generates the frequency modulated wave having the frequency pattern in which the frequency linearly increases or decreases over time.

15. The ADC calibration method according to claim 13, wherein the calibration signal generation step generates the frequency modulated wave having the frequency pattern in which the frequency increases or decreases stepwise over time.

16. The ADC calibration method according to claim 13, wherein the calibration signal generation step includes:
generating the calibration signal associated with a level on/off pattern which indicates a level-on at a leading position and a level-off at a trailing position of the calibration signal;
detecting timings of a start position and an end position of the calibration signal from the level on/off pattern in accordance with a process of the AD conversion; and
performing the frequency conversion in an period from the start position to the end position of the calibration signal.

17. The ADC calibration method according to claim 13, wherein the calibration signal generation step includes:
generating a trigger signal indicating a timing of a signal-on of the calibration signal in accordance with a generation of the frequency modulated wave;
detecting a timing of a start position of the calibration signal from the trigger signal and estimating a timing of an end position of the calibration signal based on the start position of the calibration signal and the applicable frequency range, in accordance with a process of the AD conversion; and
performing the frequency conversion in a period from the start position to the end position of the calibration signal.

18. The ADC calibration method according to claim 13, further comprising:
recognizing the applicable frequency range of the calibration signal; and
controlling a sweep speed variably by selecting the sweep speed of the calibration signal according to the applicable frequency range recognized.

19. The ADC calibration method according to claim 13, wherein
the individual frequency characteristic detection step individually detects the frequency characteristics regarding amplitude, phase, and DC offset of the sample signal by each of the plurality of AD converters, and
the mismatch calculation step includes:
calculating a difference in the frequency characteristics regarding the amplitude, the phase, and the DC offset of the sample signal by each of the plurality of AD converters as the mismatch characteristics between the plurality of AD converters;
calculating, as interpolated values, values of the amplitude, the phase, and the DC offset of the sample signal at a same frequency at a time for each of the plurality of AD converters by interpolation based on detected values of the amplitude, the phase, and the DC offset of the sample signal by each of the plurality of AD converters; and
calculating the mismatch characteristics between the plurality of AD converters based on the interpolated values of the same frequency at the time calculated by the timing interpolation processing unit.

20. The ADC calibration method according to claim 13, further comprising:
prompting calibration when the temperature sensor, which detects a temperature inside a device body, detects either a temperature below or above a temperature range which is preset;
performing an interleave correction of the TI-ADC to eliminate the mismatch characteristics between the plurality of AD converters based on the correction information calculated at the correction information calculation step; and
storing the correction information corresponding to each temperature within the temperature range to a correction information table;
performing the interleave correction by obtaining the correction information from the correction information table corresponding to the temperature inside the device body detected by the temperature sensor.
